(19) United States
(12) Patent Application Publication
(10) Pub. No.: US 2026/0179682 A1
(43) Pub. Date: Jun. 25, 2026

(54) ELECTRONIC DEVICE WITH HIGH-SPEED ARCHITECTURE

(71) Applicant: MEDIATEK INC., Hsinchu City (TW)

(72) Inventors: Manish TRIVEDI, Bengaluru KA (IN); Sandipan SINHA, Bengaluru KA (IN); Ramesh HALLI, Bengaluru KA (IN); Taha KHURSHEED, Bengaluru KA (IN)

(21) Appl. No.: 19/235,697

(22) Filed: Jun. 12, 2025

(30) Foreign Application Priority Data
Dec. 19, 2024 (IN) 202421101008

(51) Int. Cl. G11C 11/419

(52) U.S. Cl. CPC G11C 11/419

(57) ABSTRACT

An electronic device includes a bitcell, a read-write multiplexer and a word line generation block. The bitcell is electrically connected between a word line and a pair of bit lines. The bitcell performs a read operation followed by a write operation. There is a gap period between the read operation and the write operation. The read-write multiplexer discharges a bit line voltage on the pair of bit lines from an operating voltage to a predetermined voltage during the read operation. The read-write multiplexer floats the predetermined voltage during the gap period. The read-write multiplexer charges the predetermined voltage to the operating voltage or discharges the predetermined voltage to a ground voltage based on data being written into the bitcell after the gap period. The word line generation block generates a delay period after the gap period and before the write operation is performed.

### CROSS REFERENCE TO RELATED APPLICATIONS

This Application claims the benefit of India Patent Application No. 202421101008, filed on Dec. 19, 2024, the entirety of which is incorporated by reference herein.

### BACKGROUND OF THE INVENTION

### Field of the Invention

The present invention relates to an electronic device, and, in particular, it relates to a double pump 2-port SRAM with high-speed architecture.

### Description of the Related Art

Modern computer systems (CPU, GPU, NPU) incorporate two port SRAMs for better throughput while maintaining area density. Pseudo two port (P2P) SRAM uses 6T bitcell and can perform Read (R), Write (W), Read-Write (RW) operations, unlike the other two port architectures which use 8T bitcells. During an RW operation, a read operation is followed by a write operation in a single clock cycle.

Bit lines are capacitive loaded lines and take time to precharge back to full rail after discharge. With conventional P2P SRAM, word line and bit line precharge is asserted twice (double pumped) during the read and write operation. Two bit line precharge operations limit cycle time and increase dynamic power overhead. After the read operation, to ensure bit lines are precharged before the start of the write operation, a timing margin gap needs to be ensured as well, which has an additional overhead of RW operation.

### BRIEF SUMMARY OF THE INVENTION

An embodiment of the present invention provides an electronic device. The electronic device includes a bitcell, a read-write multiplexer, and a word line generation block. The bitcell is electrically connected between a word line and a pair of bit lines. The bitcell performs a read operation followed by a write operation. There is a gap period between the read operation and the write operation. The read-write multiplexer is electrically connected to the pair of bit lines, discharges a bit line voltage on the pair of bit lines from an operating voltage to a predetermined voltage during the read operation, floats the predetermined voltage during the gap period, and charges the predetermined voltage to the operating voltage or discharges the predetermined voltage to a ground voltage based on data being written into the bitcell after the gap period. The word line generation block generates a delay period after the gap period and before the write operation is performed.

The electronic device further includes a precharge circuit. The precharge circuit is electrically connected between the bitcell and the read-write multiplexer through the pair of bit lines, and precharges the bit line voltage on the pair of bit lines to the operating voltage based on a precharge command signal.

The electronic device further includes a read clock generation circuit, a common clock generation circuit, and a write clock generation circuit. The read clock generation circuit triggers a rising edge of a word line voltage on the word line during the read operation based on an internal-clock read signal. The common clock generation circuit generates a precharge command signal to control the precharge circuit for precharging. The write clock generation circuit is electrically connected to the read clock generation circuit and the common clock generation circuit, and triggers the rising edge of the word line voltage on the word line during the write operation based on an internal-clock gap signal.

According to the electronic device described above, the read clock generation circuit receives a read command signal and a clock signal to generate the internal-clock read signal, and generates the internal-clock gap signal based on the internal-clock read signal.

According to the electronic device described above, the common clock generation circuit receives a read command signal, a write command signal, and a clock signal to generate an internal-clock common signal. The common clock generation circuit generates the precharge command signal based on the internal-clock common signal.

According to the electronic device described above, the write clock generation circuit is electrically connected to the read clock generation circuit and the common clock generation circuit, receives a write command signal, and generates an internal-clock write signal based on write command signal.

According to the electronic device described above, the common clock generation circuit generates a mux selection read signal and a mux selection write signal based on the internal-clock read signal and an internal-clock selection write signal. The internal-clock selection write signal is generated by the write clock generation circuit based on the write command signal.

According to the electronic device described above, the common clock generation circuit controls the read-write multiplexer based on the mux selection read signal and the mux selection write signal.

According to the electronic device described above, the common clock generation circuit includes a reset multiplexer. The reset multiplexer resets the internal-clock common signal based on the read operation or the write operation.

According to the electronic device described above, when the read command signal is at a logic high level and the write command signal is at a logic low level, the bitcell performs the read operation. When the read command signal is at the logic low level and the write command signal is at the logic high level, the bitcell performs the write operation. When the read command signal and the write command signal are both at the logic high level, the bitcell performs the read operation followed by a write operation. When the read command signal and the write command signal are both at the logic low level, the bitcell performs no operation.

The electronic device further includes a footer device. The footer device is electrically connected to the read-write multiplexer, and reduces current leakage based a standby signal. The standby signal is asserted early before the gap period.

The electronic device further includes a sense amplifier and a write driver. The sense amplifier is electrically connected to the read-write multiplexer, and senses the bit line voltage on the pair of bit lines through a pair of read sensing signals. The write driver is electrically connected to the read-write multiplexer, and writes the data into the bitcell through a pair of write control signals.

According to the electronic device described above, the read-write multiplexer includes a first p-type transistor, a second p-type transistor, a third p-type transistor, a fourth p-type transistor, a first n-type transistor, a fifth p-type transistor, a sixth p-type transistor, and a second n-type transistor. The first p-type transistor includes a first end, a second end, and a control end. The first end is electrically connected to one of the bit lines, the second end is electrically connected to one of the read sensing signals, and the control end is electrically connected to a mux selection read signal. The second p-type transistor includes a first end, a second end, and a control end. The first end is electrically connected to the other bit line, the second end is electrically connected to the other read sensing signal, and the control end is electrically connected to the control end of the first p-type transistor. The third p-type transistor includes a first end, a second end, and a control end. The first end is electrically connected to the operating voltage, and the control end is electrically connected to a mux selection write signal. The fourth p-type transistor includes a first end, a second end, and a control end. The first end is electrically connected to the second end of the third p-type transistor, the second end is electrically connected to one of the bit lines, and the control end is electrically connected to one of the write control signals. The first n-type transistor includes a first end, a second end, and a control end. The first end is electrically connected to the second end of the fourth p-type transistor, the second end is electrically connected to the footer device, and the control end is electrically connected to the control end of the fourth p-type transistor. The fifth p-type transistor includes a first end, a second end, and a control end. The first end is electrically connected to the operating voltage, and the control end is electrically connected to the mux selection write signal. The sixth p-type transistor includes a first end, a second end, and a control end. The first end is electrically connected to the second end of the fifth p-type transistor, the second end is electrically connected to the other bit line, and the control end is electrically connected to the other write control signal. The second n-type transistor includes a first end, a second end, and a control end. The first end is electrically connected to the second end of the sixth p-type transistor, the second end is electrically connected to the footer device, and the control end is electrically connected to the control end of the sixth p-type transistor.

According to the electronic device described above, the control ends of the third p-type transistor and the fifth p-type transistor are electrically connected to a preselection write signal. The read-write multiplexer further includes an inverter, a seventh p-type transistor, an eighth p-type transistor, a third n-type transistor, a ninth p-type transistor, a fourth n-type transistor, and a fifth n-type transistor. The inverter is powered by the operating voltage, and inverts the mux selection write signal to generate an inverted mux selection write signal. The seventh p-type transistor includes a first end, a second end, and a control end. The first end is electrically connected to the operating voltage, and the control end is electrically connected to a prewrite signal. The eighth p-type transistor includes a first end, a second end, and a control end. The first end is electrically connected to the second end of the seventh p-type transistor, the second end is electrically connected to the preselection write signal, and the control end is electrically connected to a latched write-mask IO signal. The third n-type transistor incudes a first end, a second end, and a control end. The first end is electrically connected to the preselection write signal, and the control end is electrically connected to the latched write-mask IO signal. The ninth p-type transistor includes a first end, a second end, and a control end. The first end is electrically connected to the operating voltage, and the control end is electrically connected to the inverted mux selection write signal. The fourth n-type transistor incudes a first end, a second end, and a control end. The first end is electrically connected to the second end of the ninth p-type transistor, which is connected to the preselection write signal and the control end is electrically connected to the prewrite signal. The fifth n-type transistor includes a first end, a second end, and a control end. The first end is electrically connected to the second ends of the third n-type transistor and fourth n-type transistor, the second end is electrically connected to the ground voltage, and the control end is electrically connected to the inverted mux selection write signal.

According to the electronic device described above, an IO signal is a latched write-mask IO signal. When the latched write-mask IO signal is at a logic low level, the preselection write signal rises up early based on the prewrite signal falling down during the write operation to avoid a static noise margin (SNM) issue.

According to the electronic device described above, the precharge circuit includes a first p-type transistor, a second p-type transistor, and a third p-type transistor. The first p-type transistor includes a first end, a second end, and a control end. The first end is electrically connected to one of the bit lines, the second end is electrically connected to the operating voltage, and the control end is electrically connected to the precharge command signal. The second p-type transistor includes a first end, a second end, and a control end. The first end is electrically connected to the operating voltage, the second end is electrically connected to the other bit line, and the control end is electrically connected to the precharge command signal. The third p-type transistor includes a first end, a second end, and a control end. The first end is electrically connected to one of the bit lines, the second end is electrically connected to the other bit line, and the control end is electrically connected to the precharge command signal.

According to the electronic device described above, the precharge circuit further includes an inverter. The inverter is powered by the operating voltage, and is electrically connected to the control ends of the first p-type transistor, the second p-type transistor, and the third p-type transistor. The inverter inverses an inversed precharge command signal to generate the precharge command signal, and send the precharge command signal to the first p-type transistor, the second p-type transistor, and the third p-type transistor.

According to the electronic device described above, the read-write multiplexer includes a fourth p-type transistor. The fourth p-type transistor includes a first end, a second end, and a control end. The first end is electrically connected to one of the bit lines, the second end is electrically connected to one of the read sensing signals, and the control end is electrically connected to a mux selection read signal. The first n-type transistor includes a first end, a second end, and a control end. The first end is electrically connected to the first end of the fourth p-type transistor, the second end is electrically connected to a footer device, and the control end s electrically connected to one of the write control signals. The fifth p-type transistor includes a first end, a second end, and a control end. The first end is electrically connected to the other bit line, the second end is electrically connected to the other read sensing signal, and the control end is electrically connected to the mux selection read signal. The second n-type transistor includes a first end, a second end, and a control end. The first end is electrically connected to the first end of the fifth p-type transistor, the second end is electrically connected to the second end of the first n-type transistor, and the control end is electrically connected to the other write control signal. The sixth p-type transistor includes a first end, a second end, and a control end. The first end is electrically connected to one of the bit lines, and the control end is electrically connected to the other bit line. The seventh p-type transistor includes a first end, a second end, and a control end. The first end is electrically connected to the second end of the sixth p-type transistor, the second end is electrically connected to the operating voltage, and the control end is electrically connected to one of the write control signals. The eighth p-type transistor includes a first end, a second end, and a control end. The first end is electrically connected to the operating voltage, and the control end is electrically connected to the other write control signal. The ninth p-type transistor includes a first end, a second end, and a control end. The first end is electrically connected to the second end of the eighth p-type transistor, the second end is electrically connected to the other bit line, and the control end is electrically connected to one of the bit lines.

The electronic device further includes a first D latch and a second D latch. The first D latch includes a data input end, a clock input end, a data output end, and an inversed data output end. The first D latch receives the data being written into the bitcell through the data input end, receives a D-latch clock signal through the clock input end, and output a latch result through the data output end and an inversed latch result through the inversed data output end based on the data being written into the bitcell and the D-latch clock signal. The second D latch includes a data input end, a clock input end, a data output end, and an inversed data output end. The second D latch receives an IO signal through the data input end, receives the D-latch clock signal through the clock input end, and outputs a latched write-mask IO signal through the data output end based on the IO signal and the D-latch clock signal.

According to the electronic device described above, the write driver includes a first NAND gate, a first NOR gate, a second NAND gate, and a second NOR gate. The first NAND gate performs a NAND operation on the inversed latch result and the latched write-mask IO signal to obtain a first intermediate result. The first NOR gate is powered by the operating voltage, and performs a NOR operation on the first intermediate result and a mux selection write signal to obtain one of the write control signals. The second NAND gate performs the NAND operation on the latch result and the latched write-mask IO signal to obtain a second intermediate result. The second NOR gate is powered by the operating voltage, and performs the NOR operation on the second intermediate result and the mux selection write signal to obtain the other write control signal.

### BRIEF DESCRIPTION OF THE DRAWINGS

The present invention can be more fully understood by reading the subsequent detailed description and examples with references made to the accompanying drawings.

FIG. 1A is a schematic diagram of an electronic device 100 in accordance with some embodiments of the present invention.

FIG. 1B is a timing diagram of multiple control signals when the electronic device 100 in FIG. 1A performs a read operation followed by a write operation, in accordance with some embodiments of the present invention.

FIG. 2A is a schematic diagram of an internal-clock generation block 200 in the electronic device 100 when the read operation followed by the write operation is performed in accordance with some embodiments of the present invention.

FIG. 2B is a timing diagram of multiple control signals in the internal-clock generation block 200 when the read operation followed by the write operation is performed in accordance with some embodiments of the present invention.

FIG. 3A is a schematic diagram of a word line generation block 300 in the electronic device 100 when the read operation followed by the write operation is performed in accordance with some embodiments of the present invention.

FIG. 3B is a timing diagram of multiple control signals in the word line generation block 300 when the read operation followed by the write operation is performed in accordance with some embodiments of the present invention.

FIG. 4A is a schematic diagram of a precharge and multiplexer selection generation block 400 in the electronic device 100 when the read operation followed by the write operation is performed in accordance with some embodiments of the present invention.

FIG. 4B is a timing diagram of multiple control signals in the precharge and multiplexer selection generation block 400 when the read operation followed by the write operation is performed in accordance with some embodiments of the present invention.

FIG. 5A is a schematic diagram of the internal-clock generation block 200 in the electronic device 100 when only the read operation is performed in accordance with some embodiments of the present invention.

FIG. 5B is a timing diagram of multiple control signals in the internal-clock generation block 200 when only the read operation is performed in accordance with some embodiments of the present invention.

FIG. 5C is a timing diagram of multiple control signals in the precharge and multiplexer selection generation block 400 when only the read operation is performed in accordance with some embodiments of the present invention.

FIG. 5D is a timing diagram of multiple control signals in the word line generation block 300 when only the read operation is performed in accordance with some embodiments of the present invention.

FIG. 6A is a schematic diagram of the internal-clock generation block 200 in the electronic device 100 when only the write operation is performed in accordance with some embodiments of the present invention.

FIG. 6B is a timing diagram of multiple control signals in the internal-clock generation block 200 when only the write operation is performed in accordance with some embodiments of the present invention.

FIG. 6C is a timing diagram of multiple control signals in the precharge and multiplexer selection generation block 400 when only the write operation is performed in accordance with some embodiments of the present invention.

FIG. 6D is a timing diagram of multiple control signals in the word line generation block 300 when only the read operation is performed in accordance with some embodiments of the present invention.

FIG. 7A is a schematic diagram of an electronic device 700 in accordance with some embodiments of the present invention.

FIG. 7B is a timing diagram of multiple control signals when the electronic device 700 in FIG. 7A performs the read operation followed by the write operation in accordance with some embodiments of the present invention.

FIG. 8A is a schematic diagram of an electronic device 800 in accordance with some embodiments of the present invention.

FIG. 8B is a timing diagram of multiple control signals when the electronic device 800 in FIG. 8A performs the read operation followed by the write operation in accordance with some embodiments of the present invention.

### DETAILED DESCRIPTION OF THE INVENTION

In order to make the above purposes, features, and advantages of some embodiments of the present invention more comprehensible, the following is a detailed description in conjunction with the accompanying drawing.

Certain terms are used throughout the description and following claims to refer to particular components. As one skilled in the art will understand, electronic equipment manufacturers may refer to a component by different names. This document does not intend to distinguish between components that differ in name but not function. It is understood that the words “comprise”, “have” and “include” are used in an open-ended fashion, and thus should be interpreted to mean “include, but not limited to . . . ”. Thus, when the terms “comprise”, “have” or “include” used in the present invention are used to indicate the existence of specific technical features, values, method steps, operations, units or components. However, it does not exclude the possibility that more technical features, numerical values, method steps, work processes, units, components, or any combination of the above can be added.

The directional terms used throughout the description and following claims, such as: “on”, “up”, “above”, “down”, “below”, “front”, “rear”, “back”, “left”, “right”, etc., are only directions referring to the drawings. Therefore, the directional terms are used for explaining and not used for limiting the present invention. Regarding the drawings, the drawings show the general characteristics of methods, structures, or materials used in specific embodiments. However, the drawings should not be construed as defining or limiting the scope or properties encompassed by these embodiments. For example, for clarity, the relative size, thickness, and position of each layer, each area, or each structure may be reduced or enlarged.

When the corresponding component such as layer or area is referred to as being “on another component”, it may be directly on this other component, or other components may exist between them. On the other hand, when the component is referred to as being “directly on another component (or the variant thereof)”, there is no component between them. Furthermore, when the corresponding component is referred to as being “on another component”, the corresponding component and the other component have a disposition relationship along a top-view/vertical direction, the corresponding component may be below or above the other component, and the disposition relationship along the top-view/vertical direction is determined by the orientation of the device.

It should be understood that when a component or layer is referred to as being “connected to” another component or layer, it can be directly connected to this other component or layer, or intervening components or layers may be present. In contrast, when a component is referred to as being “directly connected to” another component or layer, there are no intervening components or layers present.

The electrical connection or coupling described in this disclosure may refer to direct connection or indirect connection. In the case of direct connection, the endpoints of the components on the two circuits are directly connected or connected to each other by a conductor line segment, while in the case of indirect connection, there are switches, diodes, capacitors, inductors, resistors, other suitable components, or a combination of the above components between the endpoints of the components on the two circuits, but the intermediate component is not limited thereto.

The words “first”, “second”, and “third” are used to describe components. They are not used to indicate the priority order of or advance relationship, but only to distinguish components with the same name.

It should be noted that the technical features in different embodiments described in the following can be replaced, recombined, or mixed with one another to constitute another embodiment without depart in from the spirit of the present invention.

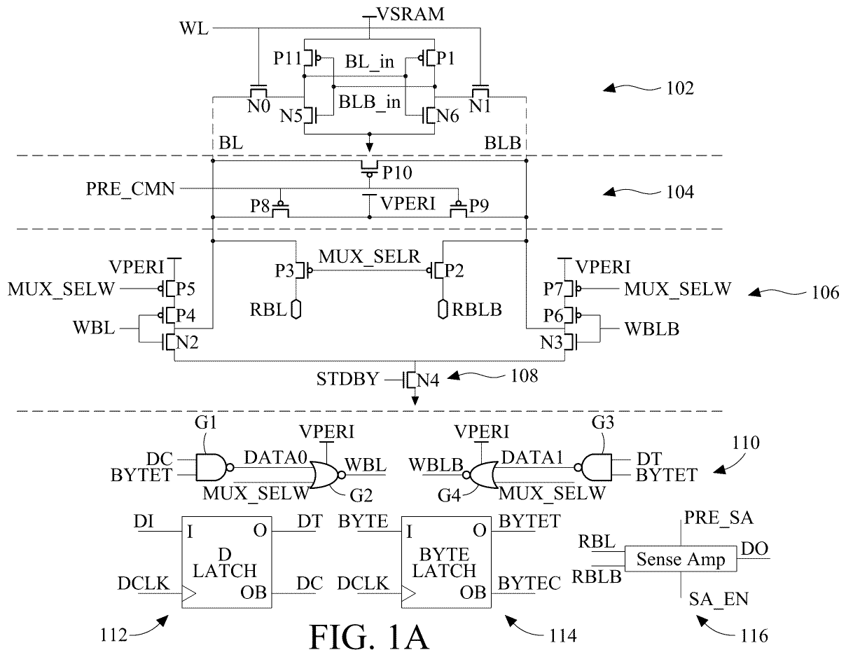

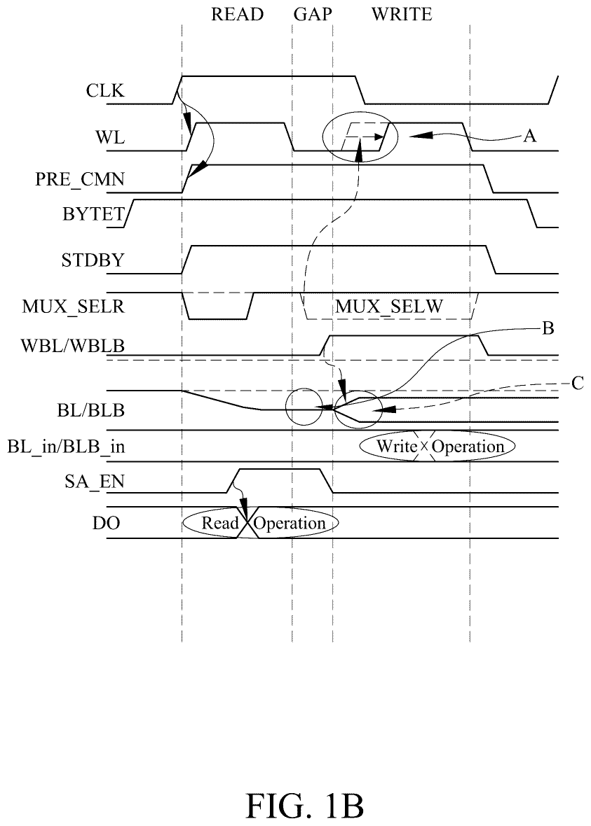

FIG. 1A is a schematic diagram of an electronic device 100 in accordance with some embodiments of the present invention. In some embodiments the electronic device 100 may be a double pump 2-port SRAM. As shown in FIG. 1A, the electronic device 100 includes a bitcell 102, a precharge circuit 104, a read-write multiplexer 106, a footer device 108, a write driver 110, a first D latch 112, a second D latch 114, and a sense amplifier 116. In some embodiments, the bitcell 102 is a 6T bitcell, but the present invention is not limited thereto. The bitcell 102 is electrically connected between a word line WL, a bit line BL, and a bit line BLB. The bitcell 102 performs a read operation followed by a write operation, so call a read-write (RW) operation. During the RW operation, there is a gap period between the read operation and the write operation, which may be described in FIG. 1B.

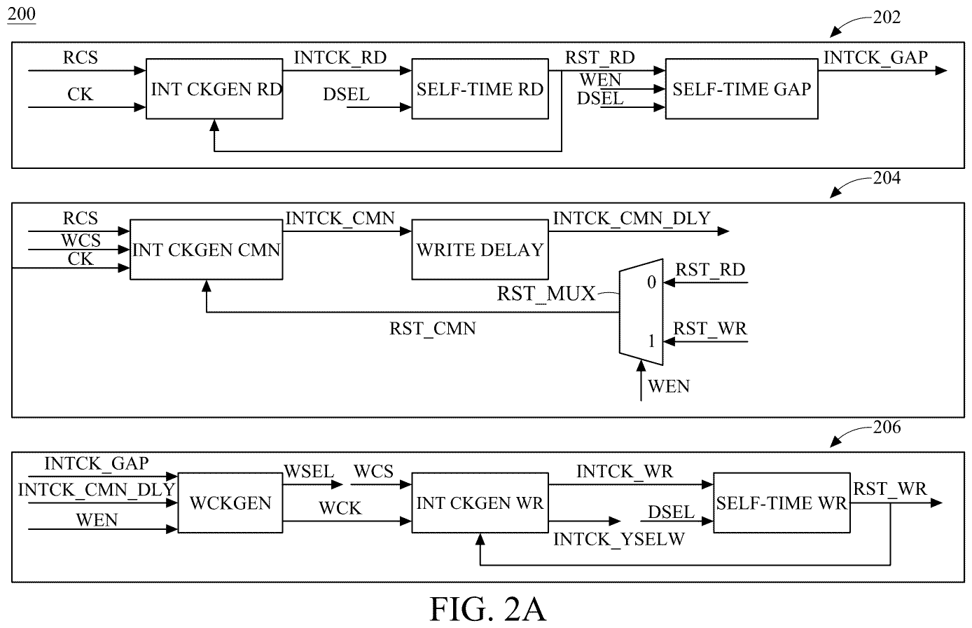

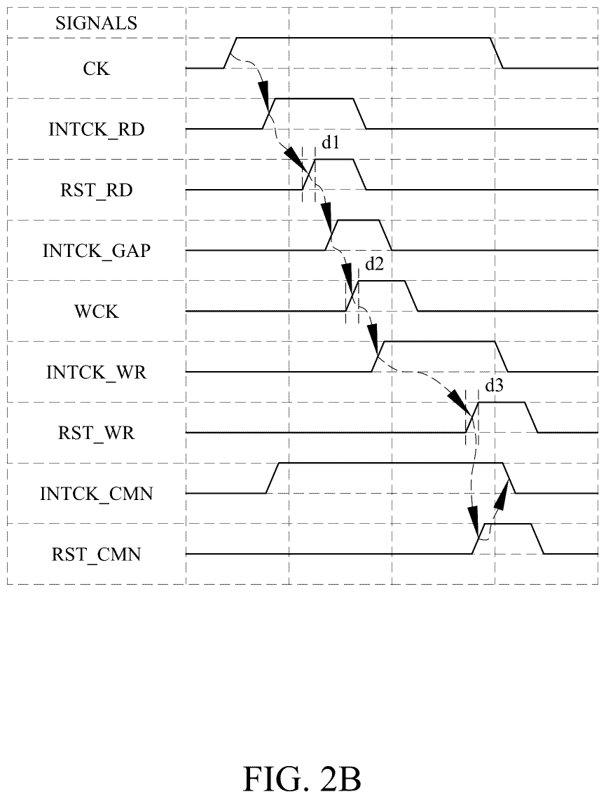

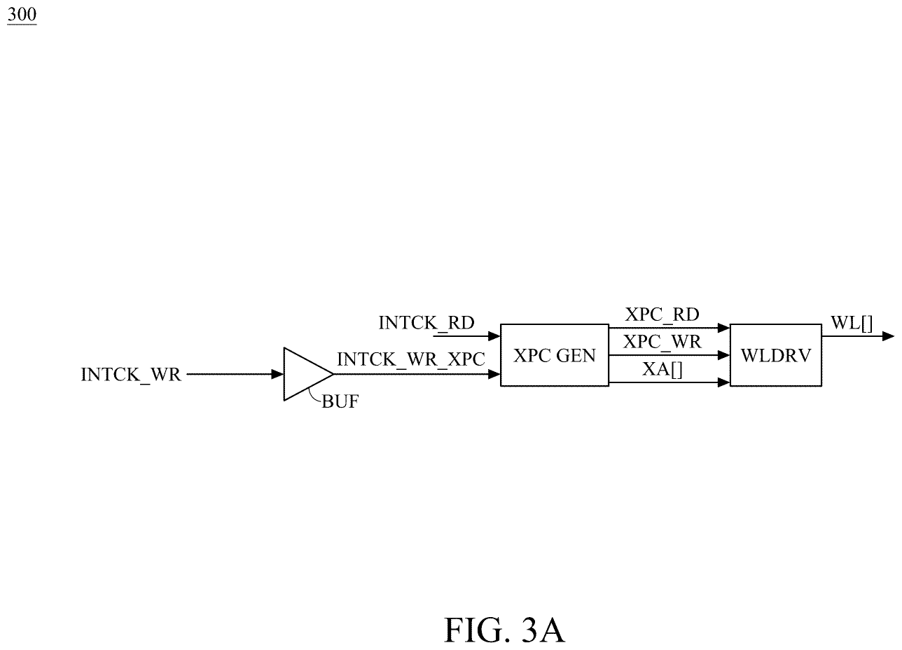

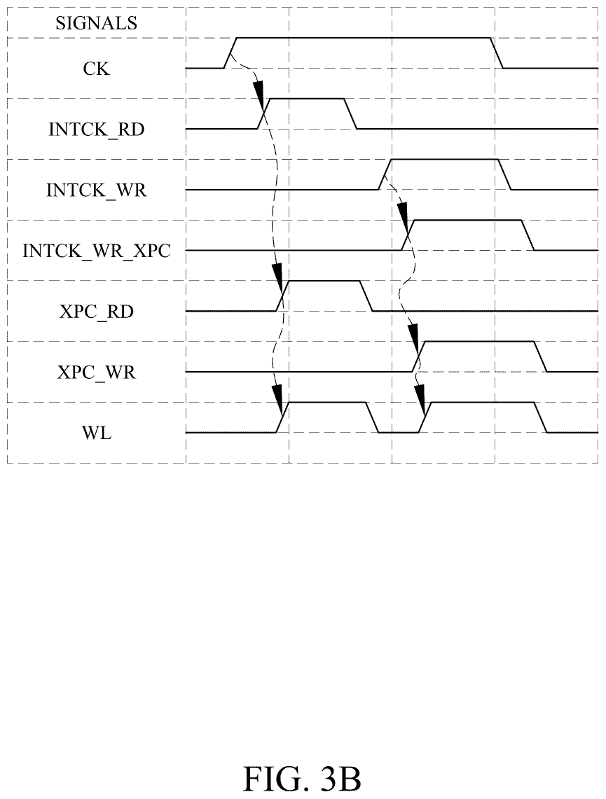

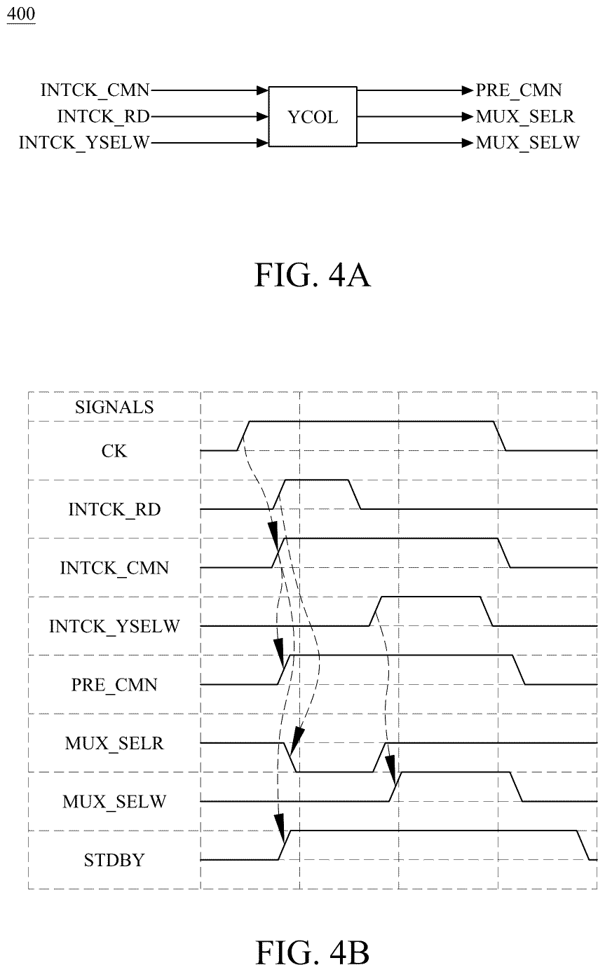

The read-write multiplexer 106 is electrically connected to the bit line BL and the bit line BLB. The read-write multiplexer 106 discharges a bit line voltage on the bit line BL and the bit line BLB from an operating voltage VPERI to a predetermined voltage during the read operation. Next, the read-write multiplexer 106 floats the predetermined voltage during the gap period. Then, the read-write multiplexer 106 charges the predetermined voltage to the operating voltage VPERI or discharges the predetermined voltage to a ground voltage based on data being written into the bitcell 102 (for example, a signal DI) after the gap period.. A word line generation block 300 illustrated in FIG. 3 generates a delay period between a mux selection write signal MUX_SELW and a voltage on the word line WL after the gap period and before the write operation is performed, which is described in FIG. 1B. In some embodiments, the operations performed by the read-write multiplexer 106 are controlled by an internal-clock generation block 200 in FIGS. 2A and 2B, a word line generation block 300 in FIGS. 3A and 3B, and a precharge and multiplexer selection generation block 400 in FIGS. 4A and 4B.

The precharge circuit 104 is electrically connected between the bitcell 102 and the read-write multiplexer 106 through the pair of bit lines (for example, the bit lines BL and BLB). The precharge circuit 104 precharges the bit line voltage on the pair of bit lines to the operating voltage VPERI based on a precharge command signal PRE_CMN from the precharge and multiplexer selection generation block 400. The footer device 108 is electrically connected to the read-write multiplexer 106, and reduces current leakage based on a standby signal STDBY. The standby signal STDBY is asserted early before the gap period. The sense amplifier 116 is electrically connected to the read-write multiplexer 106, and senses the bit line voltage on the pair of bit lines (for example, the bit lines BL and BLB) through a pair of read sensing signals RBL/RBLB. When the rising edge of an enable signal SA_EN is detected by the sense amplifier 116, the read operation is performed by the sense amplifier 116, and output signal DO is generated. The write driver 110 is electrically connected to the read-write multiplexer 106, and writes the data into the bitcell 102 through a pair of write control signals WBL/WBLB.

In some embodiments of FIG. 1A, the bitcell 102 includes a n-type transistor N0, a n-type transistor N1, a p-type transistor P1, a p-type transistor P11, a n-type transistor N5, and a n-type transistor N6. The control end of the n-type transistor N0 is electrically connected to the word line WL. The first end of the n-type transistor N0 is electrically connected to the bit line BL. The second end of the n-type transistor N0 is electrically connected to a bitcell internal line BL_in. The control end of the n-type transistor N1 is electrically connected to the word line WL. The first end of the n-type transistor N1 is electrically connected to the bit line BLB. The second end of the n-type transistor N1 is electrically connected to a bitcell internal line BLB_in. The voltage on the bitcell internal line BL_in is related to the voltage on the bit line BL. The voltage on the bitcell internal line BLB_in is related to the voltage on the bit line BLB.

The control end of the p-type transistor P11 is electrically connected to the bitcell internal line BLB_in. The first end of the p-type transistor P11 is electrically connected to a voltage VSRAM. The second end of the p-type transistor P11 is electrically connected to the bitcell internal line BL_in. The control end of the p-type transistor P1 is electrically connected to the bitcell internal line BL_in. The first end of the p-type transistor P1 is electrically connected to the voltage VSRAM. The second end of the p-type transistor P1 is electrically connected to the bitcell internal line BLB_in. The control end of the n-type transistor N5 is electrically connected to the bitcell internal line BLB_in. The first end of the n-type transistor N5 is electrically connected to the bitcell internal line BL_in. The second end of the n-type transistor N5 is electrically connected to the ground voltage. The control end of the n-type transistor N6 is electrically connected to the bitcell internal line BL_in. The first end of the n-type transistor N6 is electrically connected to the bitcell internal line BLB_in. The second end of the n-type transistor N6 is electrically connected to the ground voltage.

In some embodiments of FIG. 1A, the precharge circuit 104 includes a p-type transistor P8, a p-type transistor P9, and a p-type transistor P10. The first end of the p-type transistor P8 is electrically connected to the bit line BL. The second end of the p-type transistor P8 is electrically connected to the operating voltage VPERI. The control end of the p-type transistor P8 is electrically connected to the precharge command signal PRE_CMN. The first end of the p-type transistor P9 is electrically connected to the operating voltage VPERI. The second end of the p-type transistor P9 is electrically connected to the bit line BLB. The control end of the p-type transistor P9 is electrically connected to the precharge command signal PRE_CMN. The first end of the p-type transistor P10 is electrically connected to the bit line BL. The second end of the p-type transistor P10 is electrically connected to the bit line BLB. The control end of the p-type transistor P10 is electrically connected to the precharge command signal PRE_CMN.

In some embodiments of FIG. 1A, the read-write multiplexer 106 includes a p-type transistor P2, a p-type transistor P3, a p-type transistor P5, a p-type transistor P4, a n-type transistor N2, a p-type transistor P7, a p-type transistor P6, and a n-type transistor N3. The first end of the p-type transistor P2 is electrically connected to the bit line BLB. The second end of the p-type transistor P2 is electrically connected to the read sensing signal RBLB. The control end of the p-type transistor P2 is electrically connected to a mux selection read signal MUX_SELR. The first end of the p-type transistor P3 is electrically connected to the other one of the bit line BL. The second end of the p-type transistor P3 is electrically connected to the read sensing signal RBL. The control end of the p-type transistor P3 is electrically connected to the control end of the p-type transistor P2. The first end of the p-type transistor P5 is electrically connected to the operating voltage VPERI. The control end of the p-type transistor P5 is electrically connected to a mux selection write signal MUX_SELW. The first end of the p-type transistor P4 is electrically connected to the second end of the p-type transistor P5. The second end of the p-type transistor P4 is electrically connected to the bit line BL. The control end of the p-type transistor P4 is electrically connected to the write control signal WBL. The first end of n-type transistor N2 is electrically connected to the second end of the p-type transistor P4. The second end of n-type transistor N2 is electrically connected to the footer device 108. The control end of n-type transistor N2 is electrically connected to the control end of the p-type transistor P4.

The first end of the p-type transistor P7 is electrically connected to the operating voltage VPERI, and the control end the p-type transistor P7 is electrically connected to the mux selection write signal MUX_SELW. The first end of the p-type transistor P6 is electrically connected to the second end of the fifth p-type transistor P7. The second end of the p-type transistor P6 is electrically connected to the bit line BLB. The control end of the p-type transistor P6 is electrically connected to the write control signal WBLB. The first end of the n-type transistor N3 is electrically connected to the second end of the p-type transistor P6. The second end of the n-type transistor N3 is electrically connected to the footer device 108. The control end of the n-type transistor N3 is electrically connected to the control end of the p-type transistor P6. In some embodiments of FIG. 1A, the footer device 108 includes a n-type transistor N4. The first end of the n-type transistor N4 is electrically connected to the second ends of the n-type transistors N2 and N3. The second end of the n-type transistor N4 is electrically connected to the ground voltage. The control end of the n-type transistor N4 is electrically connected to the standby signal STDBY.

In some embodiments of FIG. 1A, the first D latch 112 includes a data input end (I), a clock input end, a data output end (O), and an inversed data output end (OB). The first D latch 112 receives the data being written into the bitcell (DI) through the data input end, receives a D-latch clock signal DCLK through the clock input end, and outputs a latch result DT through the data output end. The first D latch 112 further outputs an inversed latch result DC through the inversed data output end based on the data being written into the bitcell (DI) and the D-latch clock signal DCLK. In some embodiments of FIG. 1A, the second D latch 114 includes a data input end (I), a clock input end, a data output end (O), and an inversed data output end (OB). The second D latch 114 receives an IO signal BYTE through the data input end, receives the D-latch clock signal DCLK through the clock input end, and outputs a latched write-mask IO signal BYTET through the data output end based on the IO signal BYTE and the D-latch clock signal DCLK.

In some embodiments of FIG. 1A, the write driver 110 includes a NAND gate G1, a NOR gate G2, a NAND gate G3, and a NOR gate G4. The NAND gate G1 performs a NAND operation on the inversed latch result DC and the latched write-mask IO signal BYTET to obtain a first intermediate result DATA0. The NOR gate G2 is powered by the operating voltage VPERI. The NOR gate G2 performs a NOR operation on the first intermediate result DATA0 and the mux selection write signal MUX_SELW to obtain the write control signal WBL. The NAND gate G3 performs the NAND operation on the latch result DT and the latched write-mask IO signal BYTET to obtain a second intermediate result DATA1. The NOR gate G4 is powered by the operating voltage. The NOR gate G4 performs the NOR operation on the second intermediate result DATA1 and the mux selection write signal MUX_SELW to obtain the write control signal WBLB.

FIG. 1B is a timing diagram of multiple control signals when the electronic device 100 in FIG. 1 performs a read operation followed by a write operation in accordance with some embodiments of the present invention. As shown in FIG. 1B, the control signals include a clock signal CLK, the waveform on the word line WL, the precharge command signal PRE_CMN, the latched write-mask IO signal BYTET, the standby signal STDBY, a mux selection read signal MUX_SELR, the mux selection write signal MUX_SELW, the write control signals WBL/WBLB, the waveform on the bit lines BL/BLB, the waveform on the bitcell internal lines BL_in/BLB_in, the enable signal SA_EN, and the output signal DO. The read operation starts after the rising edge of the clock signal CLK is triggered. The rising edge of the clock signal CLK then triggers the voltage on the word line WL and the precharge command signal PRE_CMN to be pulled up. The latched write-mask IO signal BYTET is always high during the read operation, the gap period and the write operation. The standby signal STDBY is pulled up after the read operation starts. The mux selection read signal MUX_SELR is pulled down to turn on the p-type transistors P2 and P3, so that the sense amplifier 116 is able to sense the bit line voltage on the bit lines BL and BLB during the read operation. At time same time, the bit line voltage on the bit lines BL and BLB is discharged to a predetermined voltage due to the sensing of the bit line voltage by the sense amplifier 116. The voltage on the bitcell internal lines BL_in/BLB_in is unchanged during the read operation. The enable signal SA_EN is pulled high during the read operation, so that the read operation is performed by the sense amplifier 116 and output signal DO is generated. The pulled high mux selection write signal MUX_SELW and the pulled low write control signals WBL/WBLB enable the read-write multiplexer 106 to float the predetermined voltage during the read operation and the gap period, for example, action B in FIG. 1B.

After the voltage on the word line WL is pulled low, the gap period between the read operation and the write operation starts. The mux selection write signal MUX_SELW is pulled low during the gap period, the word line generation block 300 generates a delay period between the mux selection write signal MUX_SELW and the voltage on the word line WL after the gap period and before the write operation is performed, for example, action A in FIG. 1B. The write control signals WBL/WBLB are pulled up during the gap period, so that the read-write multiplexer 106 is triggered to charge the predetermined voltage to a required high voltage for the write operation, such as the operating voltage VPERI, or discharge the predetermined voltage to a required low voltage, such as a ground voltage, based on data being written into the bitcell (DI) after the gap period, for example, action C in FIG. 1B. In some embodiments, the read-write multiplexer 106 entangles the mux selection write signal MUX_SELW and the write control signals WBL/WBLB to drive the voltage on the bit lines BL and BLB for writing into the bitcell 102 when the IO signal BYTE is at logic high level (BYTE=“1”). The read-write multiplexer 106 entangles the mux selection write signal MUX_SELW and the write control signals WBL/WBLB to precharge the voltage on the bit lines BL and BLB back to the operating voltage VPERI in between the read operation and the write operation when the IO signal BUTE is at logic low level (BYTE=“0”).

Once the voltage on the word line WL during the read operation resets the mux selection write signal MUX_SELW to go low, for the IO signal BYTE is at logic high level (BYTE=“1”), the floating of the bit line voltage on the bit lines BL and BLB may go to “0” or “1” depending on the data being written into the bitcell (DI). If the data being written into the bitcell (DI) match with the state of the bit lines BL and BLB, there will not be any in-between precharge on the bit lines BL and BLB, thus improving dynamic power and performance. In some embodiments, for the IO signal BYTE is at the logic low level (BYTE=“0”) and the write control signals WBL/WBLB are at the logic low level, when the mux selection write signal MUX is pulled low after the read operation, p-type transistors P4, P5, P6, and P7 are turned on, resulting into the precharge on the bit lines BL and BLB after the read operation, avoiding unwanted bitcell flip in no write operation.

Since the write operation is delayed by the pulling down of the mux selection write signal MUX_SELW, the read-write multiplexer 106 is able to charge the predetermined voltage to the required high voltage, or discharge the predetermined voltage to the required low voltage for the write operation during the delay period. The write operation is delayed by the pulling down of the mux selection write signal MUX_SELW, which is ensured by an internal-clock generation block 200 in FIG. 2A, a word line generation block 300 in FIG. 3A, and a precharge and multiplexer selection generation block 400 in FIG. 4A. When needed, the above-mentioned blocks enable the bit line voltage on the bit lines BL and BLB to precharge to the operating voltage VPERI before the rising edge of the voltage on the word line WL. The read-write multiplexer 106 controlled by the internal-clock generation block 200 in FIG. 2A, the word line generation block 300 in FIG. 3A, and the precharge and multiplexer selection generation block 400 in FIG. 4A also acts as data controlled cross pullup, this improving writability in ultra-low voltage region.

FIG. 2A is a schematic diagram of an internal-clock generation block 200 in the electronic device 100 when the read operation followed by the write operation is performed in accordance with some embodiments of the present invention. As shown in FIG. 2A, the electronic device 100 includes the internal-clock generation block 200. The internal-clock generation block 200 includes a read clock generation circuit 202, a common clock generation circuit 204, and a write clock generation circuit 206. The read clock generation circuit 202 trigger a rising edge of a word line voltage on the word line WL during the read operation based on an internal-clock read signal INTCK_RD. The read clock generation circuit 202 receives a read command signal RCS and a clock signal CK to generate the internal-clock read signal INTCK_RD, and generates the internal-clock gap signal INTCK_GAP based on the internal-clock read signal INTCK_RD. In detail, the read clock generation circuit 202 includes a first circuit block (INT CKGEN RD), a second circuit block (SELF-TIME RD), and a third circuit block (SELF-TIME GAP). The first circuit block (INT CKGEN RD) generates the internal-clock read signal INTCK_RD based on the read command signal RCS and the clock signal CK. The second circuit block (SELF-TIME RD) generates a reset read signal RST_RD based on the internal-clock read signal INTCK_RD and a delay selection signal DSEL. In some embodiments, the reset read signal RST_RD has feedback to the first circuit block (INT CKGEN RD), so that the first circuit block (INT CKGEN RD) generates the internal-clock read signal INTCK_RD based on the read command signal RCS, the clock signal CK, and the feedback reset read signal RST_RD. The third circuit block (SELF-TIME GAP) generates the internal-clock gap signal INTCK_GAP based on the reset read signal RST_RD, a word line enable signal WEN, and the delay selection signal DSEL.

In some embodiments of FIG. 2A, the common clock generation circuit 204 generates the precharge command signal PRE_CMN based on an internal-clock common signal INTCK_CMN to control the precharge circuit for precharging. The common clock generation circuit 204 receives the read command signal RCS, a write command signal WCS, and the clock signal CK to generate the internal-clock common signal INTCK_CMN. In detail, the common clock generation circuit 204 includes a fourth circuit block (INT CKGEN CMN), a fifth circuit block (WRITE DELAY), and a reset multiplexer RST_MUX. The fourth circuit block (INT CKGEN CMN) generates the internal-clock common signal INTCK_CMN based on the read command signal RCS, the write command signal WCS, and the clock signal CK. The fifth circuit block (WRITE DELAY) generates a delay internal-clock common signal INTCK_CMN_DLY based on the internal-clock common signal INTCK_CMN. The reset multiplexer RST_MUX sends a reset command signal RST_CMN to the fourth circuit block (INT CKGEN CMN) to reset the internal-clock common signal INTCK_CMN based on the read operation or the write operation. For example, when the write enable signal WEN is at logic high level, for example, “1”, the reset multiplexer RST_MUX sends the reset command signal RST_CMN which is the same as a reset write signal RST_WR to the fourth circuit block (INT CKGEN CMN). When the write enable signal WEN is at the logic low level, for example, “0”, the reset multiplexer RST_MUX sends the reset command signal RST_CMN which is the same as a reset read signal RST_RD to the fourth circuit block (INT CKGEN CMN).

In some embodiments, the common clock generation circuit 204 generates a mux selection read signal MUX_SELR and a mux selection write signal MUX_SELW based on the internal-clock read signal INTCK_RD and an internal-clock selection write signal INTCK_YSELW. The internal-clock selection write signal INTCK_YSELW is generated by the write clock generation circuit 206 based on the write command signal WCS.

In some embodiments of FIG. 2A, the write clock generation circuit 206 is electrically connected to the read clock generation circuit 202 and the common clock generation circuit 204. The write clock generation circuit 206 triggers the rising edge of the word line voltage on the word line during the write operation based on an internal-clock gap signal INTCK_GAP. The write clock generation circuit 206 receives a write command signal WCS, and generates an internal-clock write signal INTCK_WR based on write command signal WCS. In detail, the write clock generation circuit 206 includes a sixth circuit block (WCKGEN), a seventh circuit block (INT CKGEN WR), and an eighth circuit block (SELF-TIME WR). The sixth circuit block (WCKGEN) generates a write mode selection signal WSEL and a write clock WCK based on the internal-clock gap signal INTCK_GAP from the read clock generation circuit 202, the delay internal-clock common signal INTCK_CMN_DLY from the common clock generation circuit 204, and the write enable signal WEN. The seventh circuit block (INT CKGEN WR) generates the internal-clock write signal INTCK_WR and an internal-clock selection write signal INTCK_YSELW based on the write command signal WCS and the write clock WCK. The eighth circuit block (SELF-TIME WR) generates the reset write signal RST_WR based on the internal-clock write signal INTCK_WR and the delay selection signal DSEL.

FIG. 2B is a timing diagram of multiple control signals in the internal-clock generation block 200 when the read operation followed by the write operation is performed in accordance with some embodiments of the present invention. The control signals in FIG. 2B include the clock signal CK, the internal-clock read signal INTCK_RD, the reset read signal RST_RD, the internal-clock gap signal INTCK_GAP, the write clock WCK, the internal-clock write signal INTCK_WR, the reset write signal RST_WR, the internal-clock common signal INTCK_CMN, and the reset command signal RST_CMN. As shown in FIG. 2B, the clock signal CK triggers the internal-clock read signal INTCK_RD though the first circuit block (INT CKGEN RD). The internal-clock read signal INTCK_RD triggers the reset read signal RST_RD with a delay d1 through the second circuit block (SELF-TIME RD). The delay d1 is a tunable delay which can be determined by the second circuit block (SELF-TIME RD).

Next, the reset read signal RST_RD triggers the internal-clock gap signal INTCK_GAP with a delay d2 through the third circuit block (SELF-TIME GAP). The delay d2 is a tunable delay which can be determined by the third circuit block (SELF-TIME GAP). The internal-clock gap signal INTCK_GAP triggers the write clock WCK through the sixth circuit block (WCKGEN). The write clock WCK triggers the internal-clock write signal INTCK_WR through the seventh circuit block (INT CKGEN WR). The internal-clock write signal INTCK_WR triggers the reset write signal RST_WR with a delay d3 through the eighth circuit block (SELF-TIME WR). The delay d3 is a tunable delay which can be determined by the eighth circuit block (SELF-TIME WR). When the write enable signal WEN is at logic high level, for example, “1”, the reset write signal RST_WR triggers the reset command signal RST_CMN through the reset multiplexer RST_MUX. The reset command signal RST_CMN triggers the internal-clock common signal INTCK_CMN to pull low, so that the internal-clock common signal INTCK_CMN is reset.

FIG. 3A is a schematic diagram of a word line generation block 300 in the electronic device 100 when the read operation followed by the write operation is performed in accordance with some embodiments of the present invention. The word line generation block 300 may be included in the read clock generation circuit 202 and the write clock generation circuit 206, or may be electrically connected to the read clock generation circuit 202 and the write clock generation circuit 206. As shown in FIG. 3A, the word line generation block 300 includes a buffer BUF, a ninth circuit block (XPC GEN), and a tenth circuit block (WLDRV). The internal-clock write signal INTCK_WR from the write clock generation circuit 206 passes through the buffer BUF to become an internal-clock write signal INTCK_WR_XPC. The ninth circuit block (XPC GEN) generates a read signal XPC_RD based on the internal-clock read signal INTCK_RD. The ninth circuit block (XPC GEN) generates a write signal XPC_WR based on the internal-clock write signal INTCK_WR_XPC. The ninth circuit block (XPC GEN) further generates an indication signal XA[] to determine which word line is pulled up. During the read operation, the tenth circuit block (WLDRV) generates the word line voltage WL[] based on the read signal XPC_RD. During the write operation, the tenth circuit block (WLDRV) generates the word line voltage WL[] based on the write signal XPC_WR.

FIG. 3B is a timing diagram of multiple control signals in the word line generation block 300 when the read operation followed by the write operation is performed in accordance with some embodiments of the present invention. The control signals in FIG. 3B include the clock signal CK, the internal-clock read signal INTCK_RD, the internal-clock write signal INTCK_WR, the internal-clock write signal INTCK_WR_XPC, the read signal XPC_RD, the write signal XPC_WR, and the word line voltage WL[]. As shown in FIG. 3B, the clock signal CK triggers the internal-clock read signal INTCK_RD. During the read operation, the internal-clock read signal INTCK_RD triggers the read signal XPC_RD, and the read signal XPC_RD triggers the word line voltage WL[]. During the write operation, the internal-clock write signal INTCK_WR_XPC triggers the write signal XPC_WR, and the write signal XPC_WR triggers the word line voltage WL[].

FIG. 4A is a schematic diagram of a precharge and multiplexer selection generation block 400 in the electronic device 100 when the read operation followed by the write operation is performed in accordance with some embodiments of the present invention. The precharge and multiplexer selection generation block 400 may be included in the common clock generation circuit 204. As shown in FIG. 4A, the precharge and multiplexer selection generation block 400 includes an eleventh circuit block (YCOL). The eleventh circuit block (YCOL) generates the precharge command signal PRE_CMN based on the internal-clock common signal INTCK_CMN. The eleventh circuit block (YCOL) generates the mux selection read signal MUX_SELR based on the internal-clock read signal INTCK_RD. The eleventh circuit block (YCOL) generates the mux selection write signal MUX_SELW based on the internal-clock selection write signal INTCK_YSELW.

FIG. 4B is a timing diagram of multiple control signals in the precharge and multiplexer selection generation block 400 when the read operation followed by the write operation is performed in accordance with some embodiments of the present invention. The control signals in FIG. 4B include the clock signal CK, the internal-clock read signal INTCK_RD, the internal-clock common signal INTCK_CMN, the internal-clock selection write signal INTCK_YSELW, the precharge command signal PRE_CMN, the mux selection read signal MUX_SELR, the mux selection write signal MUX_SELW, and the standby signal STDBY. As shown in FIG. 4B, during the read operation, the clock signal CK triggers the internal-clock common signal INTCK_CMN. The internal-clock common signal INTCK_CMN triggers both the precharge command signal PRE_CMN and the standby signal STDBY. The internal-clock read signal INTCK_RD triggers the mux selection read signal MUX_SELR to pull low. During the write operation, the internal-clock selection write signal INTCK_YSELW triggers the mux selection write signal MUX_SELW to pull high.

In some embodiments, when the read command signal RCS is at the logic high level and the write command signal WCS is at the logic low level, the bitcell 102 performs the read operation. When the read command signal RCS is at the logic low level and the write command signal WCS is at the logic high level, the bitcell 102 performs the write operation. When the read command signal RCS is at the logic high level and the write command signal WCS is at the logic high level, the bitcell 102 performs the read operation followed by the write operation. When the read command signal RCS and the write command signal WCS are both at the logic low level, the bitcell 102 performs no operation.

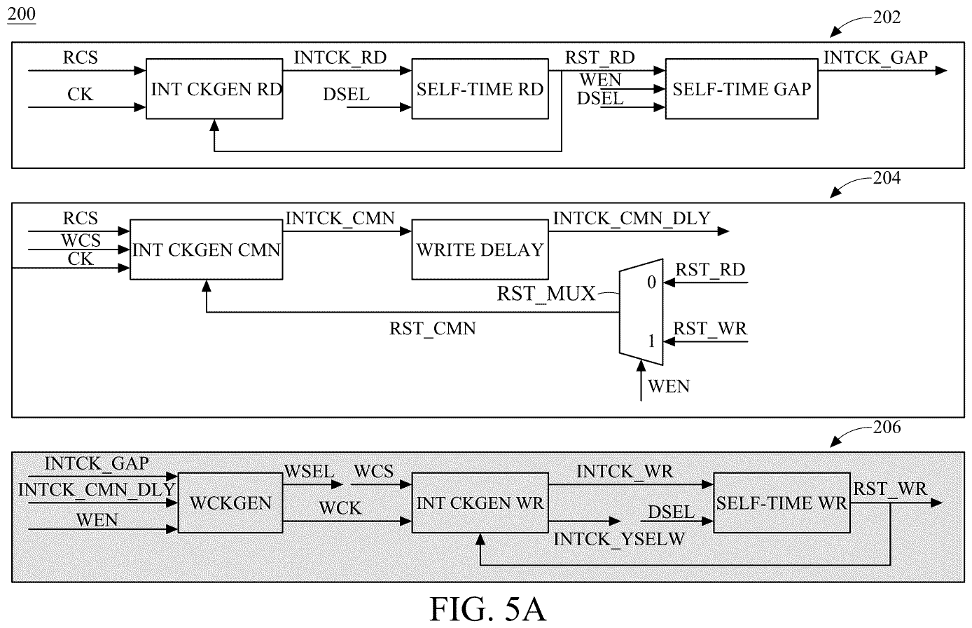

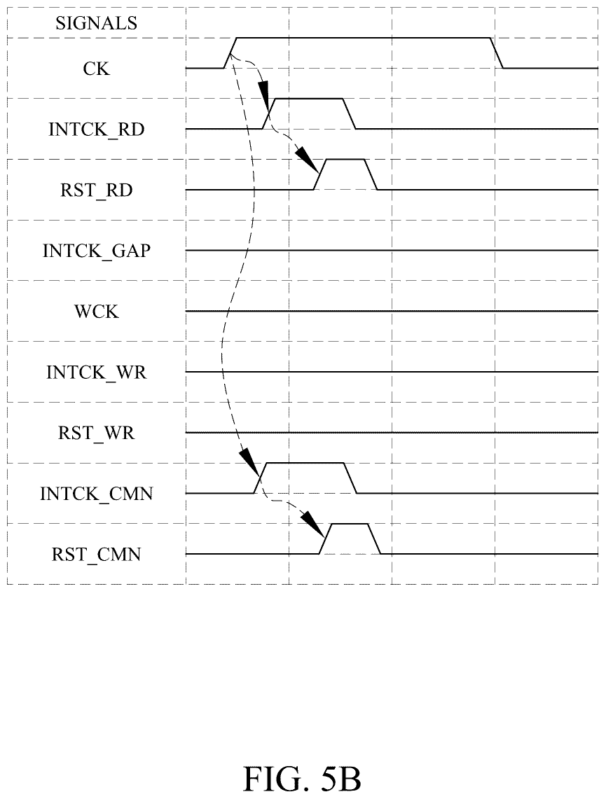

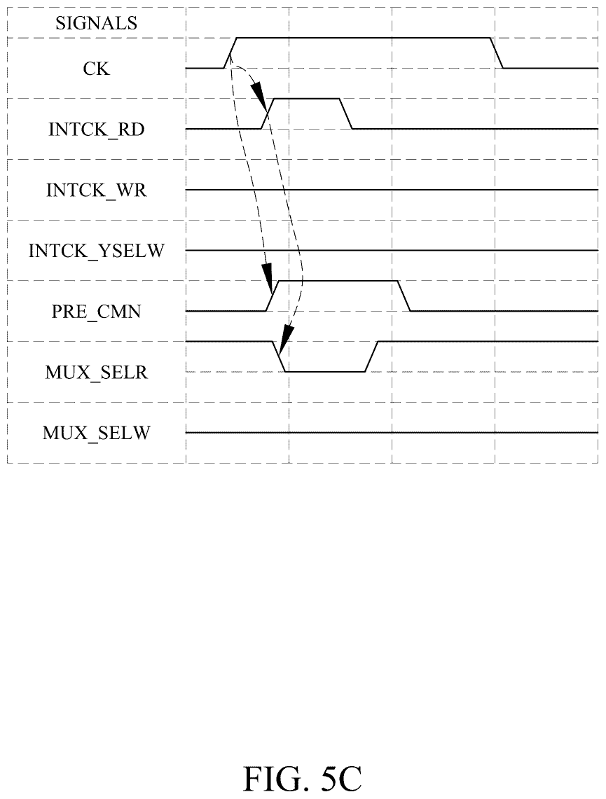

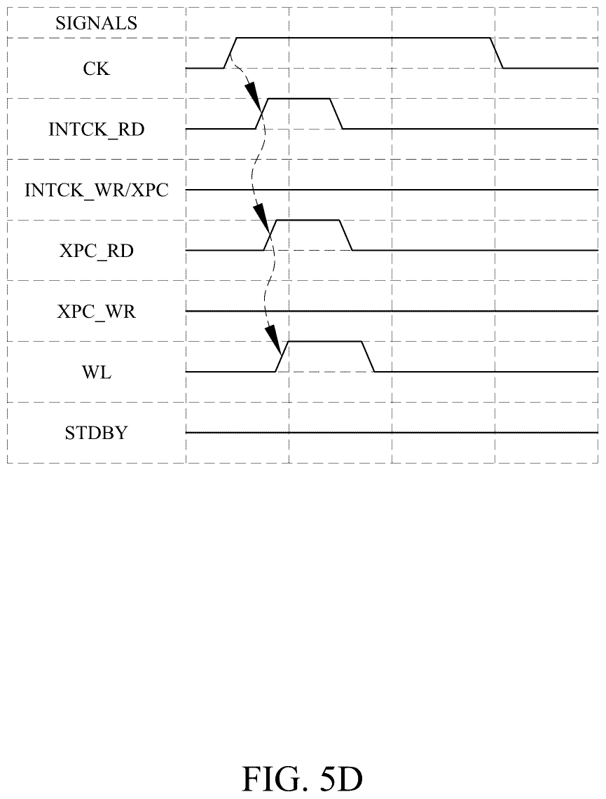

FIG. 5A is a schematic diagram of the internal-clock generation block 200 in the electronic device 100 when only the read operation is performed in accordance with some embodiments of the present invention. As shown in FIG. 5A, when only the read operation is performed, the read clock generation circuit 202 and the common clock generation circuit 204 are activated. However, the write clock generation circuit 206 does not activated, so that the power consumption of the electronic device 100 may be reduced.

FIG. 5B is a timing diagram of multiple control signals in the internal-clock generation block 200 when only the read operation is performed in accordance with some embodiments of the present invention. The control signals in FIG. 5B include the clock signal CK, the internal-clock read signal INTCK_RD, the reset read signal RST_RD, the internal-clock gap signal INTCK_GAP, the write clock WCK, the internal-clock write signal INTCK_WR, the reset write signal RST_WR, the internal-clock common signal INTCK_CMN, and the reset command signal RST_CMN. As shown in FIG. 5B, the clock signal CK triggers the internal-clock read signal INTCK_RD through the first circuit block (INT CKGEN RD) in the read clock generation circuit 202. The clock signal CK further triggers the internal-clock common signal INTCK_CMN through the fourth circuit block (INT CKGEN CMN) in the common clock generation circuit 204. Then, the internal-clock read signal INTCK_RD triggers the reset read signal RST_RD through the second circuit block (SELF-TIME RD) in the read clock generation circuit 202. The internal-clock common signal INTCK_CMN triggers the reset command signal RST_CMN. Since no write operation is performed, the internal-clock gap signal INTCK_GAP, the write clock WCK, and the internal-clock write signal INTCK_WR are always at the logic low level during the read operation.

FIG. 5C is a timing diagram of multiple control signals in the precharge and multiplexer selection generation block 400 when only the read operation is performed in accordance with some embodiments of the present invention. The control signals in FIG. 5C include the clock signal CK, the internal-clock read signal INTCK_RD, the internal-clock write signal INTCK_WR, the internal-clock selection write signal INTCK_YSELW, the precharge command signal PRE_CMN, the mux selection read signal MUX_SELR, and the mux selection write signal MUX_SELW. As shown in FIG. 5C, the clock signal CK triggers the internal-clock read signal INTCK_RD through the first circuit block (INT CKGEN RD) in the read clock generation circuit 202. The clock signal CK further triggers the precharge command signal PRE_CMN through the precharge and multiplexer selection generation block 400. The, the internal-clock read signal INTCK_RD triggers the mux selection read signal MUX_SELR to pull low. Since no write operation is performed, the internal-clock write signal INTCK_WR, the internal-clock selection write signal INTCK_YSELW, and the mux selection write signal MUX_SELW are always at the logic low level during the read operation.

FIG. 5D is a timing diagram of multiple control signals in the word line generation block 300 when only the read operation is performed in accordance with some embodiments of the present invention. The control signals in FIG. 5D include the clock signal CK, the internal-clock read signal INTCK_RD, the internal-clock write signal INTCK_WR_XPC, the read signal XPC_RD, the write signal XPC_WR, the word line voltage WL[], and the standby signal STDBY. As shown in FIG. 5D, the clock signal CK triggers the internal-clock read signal INTCK_RD through the first circuit block (INT CKGEN RD) in the read clock generation circuit 202. Next, the internal-clock read signal INTCK_RD triggers the read signal XPC_RD through the ninth circuit block (XPC GEN) in the word line generation block 300. The read signal XPC_RD triggers the word line voltage WL[] through the tenth circuit block (WLDRV). Since no write operation is performed, the internal-clock write signal INTCK_WR_XPC and the mux selection write signal MUX_SELW are always at the logic low level during the read operation. In some embodiments of FIG. 5D, the standby signal STDBY is always at the logic low level during the read operation.

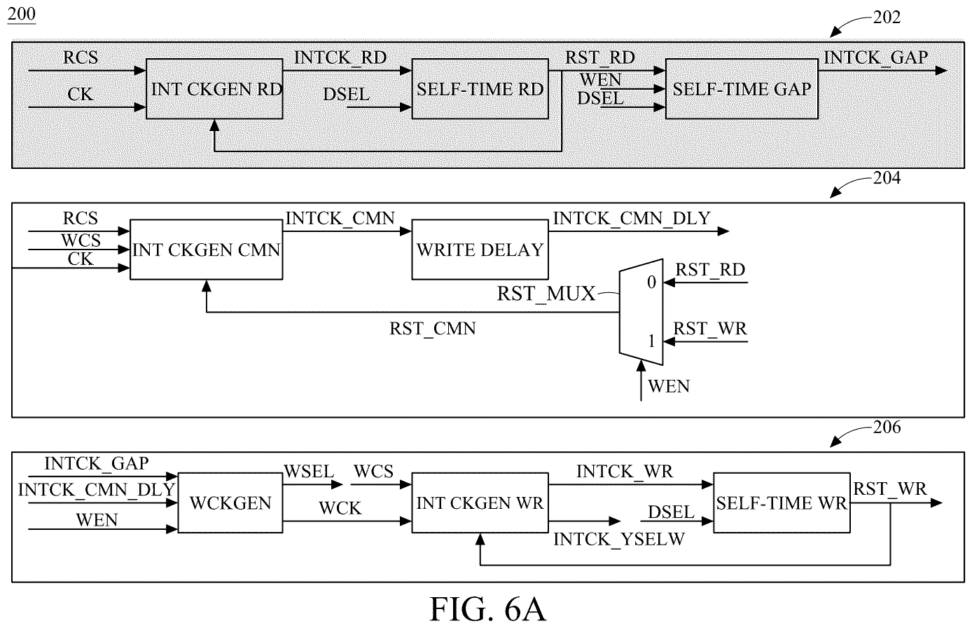

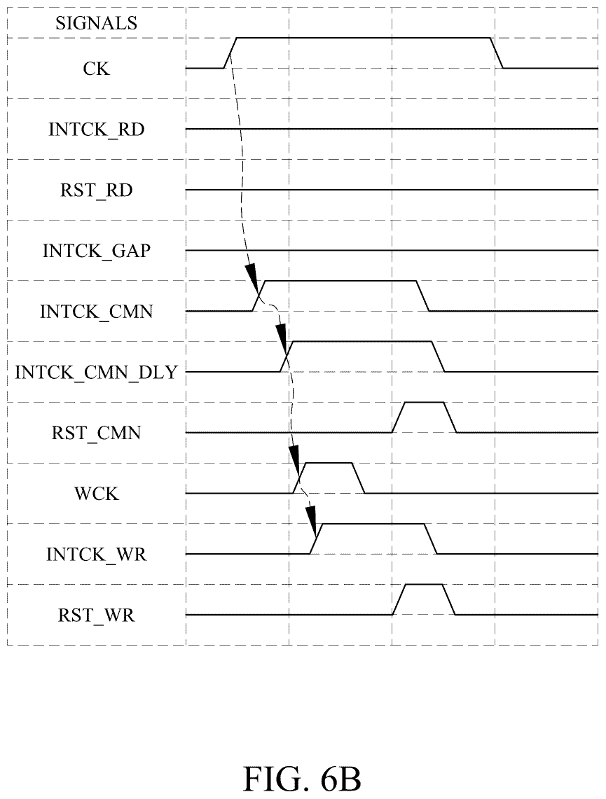

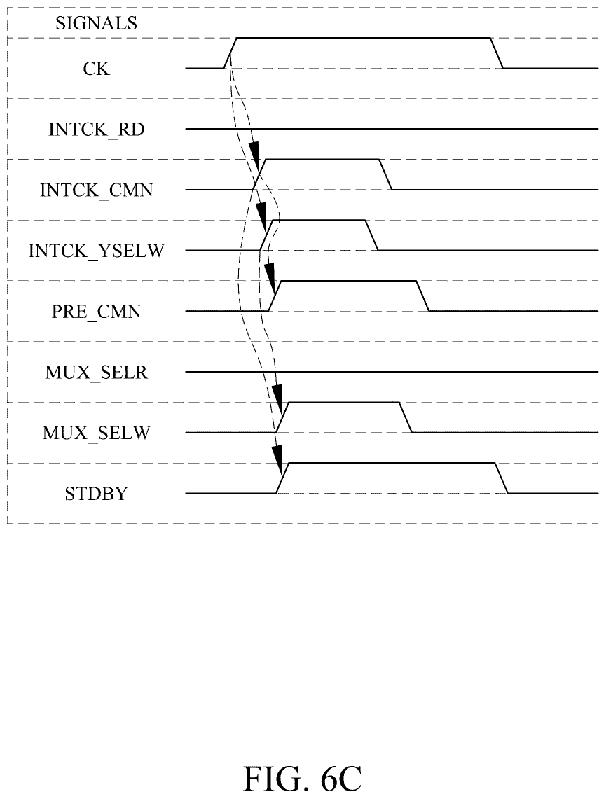

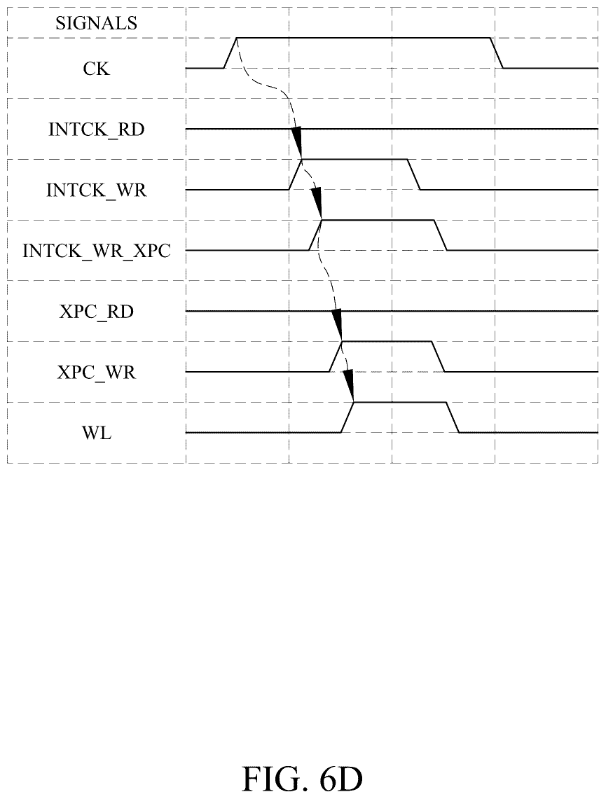

FIG. 6A is a schematic diagram of the internal-clock generation block 200 in the electronic device 100 when only the write operation is performed in accordance with some embodiments of the present invention. As shown in FIG. 6A, when only the write operation is performed, the common clock generation circuit 204 and the write clock generation circuit 206 are activated. However, the read clock generation circuit 202 does not activated, so that the power consumption of the electronic device 100 may be reduced.

FIG. 6B is a timing diagram of multiple control signals in the internal-clock generation block 200 when only the write operation is performed in accordance with some embodiments of the present invention. The control signals in FIG. 6B include the clock signal CK, the internal-clock read signal INTCK_RD, the reset read signal RST_RD, the internal-clock gap signal INTCK_GAP, the internal-clock common signal INTCK_CMN, the delay internal-clock common signal INTCK_CMN_DLY, the reset command signal RST_CMN, the write clock WCK, the internal-clock write signal INTCK_WR, and the reset write signal RST_WR. As shown in FIG. 6B, the clock signal CK triggers the internal-clock common signal INTCK_CMN through the fourth circuit block (INT CKGEN CMN) in the common clock generation circuit 204. Next, the internal-clock common signal INTCK_CMN triggers the delay internal-clock common signal INTCK_CMN_DLY through the fifth circuit block (WRITE DELAY) in the common clock generation circuit 204. The delay internal-clock common signal INTCK_CMN_DLY triggers the write clock WCK through the sixth circuit block (WCKGEN). The write clock WCK triggers the internal-clock write signal INTCK_WR through the seventh circuit block (INT CKGEN WR). The internal-clock write signal INTCK_WR triggers the reset write signal RST_WR through the eighth circuit block (SELF-TIME WR). The reset write signal RST_WR triggers the reset command signal RST_CMN through the reset multiplexer RST_MUX. Since no read operation is performed, the internal-clock read signal INTCK_RD, the reset read signal RST_RD, and the internal-clock gap signal INTCK_GAP are always at the logic low level during the write operation.

FIG. 6C is a timing diagram of multiple control signals in the precharge and multiplexer selection generation block 400 when only the write operation is performed in accordance with some embodiments of the present invention. The control signals in FIG. 6C include the clock signal CK, the internal-clock read signal INTCK_RD, the internal-clock common signal INTCK_CMN, the internal-clock selection write signal INTCK_YSELW, the precharge command signal PRE_CMN, the mux selection read signal MUX_SELR, the mux selection write signal MUX_SELW, and the standby signal STDBY. As shown in FIG. 6C, the clock signal CK triggers the internal-clock common signal INTCK_CMN through the fourth circuit block (INT CKGEN CMN) in the common clock generation circuit 204. The clock signal CK further triggers the internal-clock selection write signal INTCK_YSELW through the seventh circuit block (INT CKGEN WR) in the write clock generation circuit 206. Next, the internal-clock common signal INTCK_CMN triggers both the precharge command signal PRE_CMN through the precharge and multiplexer selection generation block 400. The internal-clock common signal INTCK_CMN further triggers the standby signal STDBY during the write operation. The internal-clock selection write signal INTCK_YSELW triggers the mux selection write signal MUX_SELW through the precharge and multiplexer selection generation block 400. Since no read operation is performed, the internal-clock read signal INTCK_RD and the mux selection read signal MUX_SELR are always at the logic low level during the write operation.

FIG. 6D is a timing diagram of multiple control signals in the word line generation block 300 when only the read operation is performed in accordance with some embodiments of the present invention. The control signals in FIG. 6D include the clock signal CK, the internal-clock read signal INTCK_RD, the internal-clock write signal INTCK_WR, the internal-clock write signal INTCK_WR_XPC, the read signal XPC_RD, the write signal XPC_WR, and the word line voltage WL[]. As shown in FIG. 6D, the clock signal CK triggers the internal-clock write signal INTCK_WR through the seventh circuit block (INT CKGEN WR) in the write clock generation circuit 206. Next, the internal-clock write signal INTCK_WR triggers the internal-clock write signal INTCK_WR_XPC through the buffer BUF in the word line generation block 300. The internal-clock write signal INTCK_WR_XPC triggers the write signal XPC_WR through the ninth circuit block (XPC GEN) in the word line generation block 300. The write signal XPC_WR triggers the word line voltage WL[] through the tenth circuit block (WLDRV) in the word line generation block 300. Since no read operation is performed, the internal-clock read signal INTCK_RD and the read signal XPC_RD are always at the logic low level during the write operation.

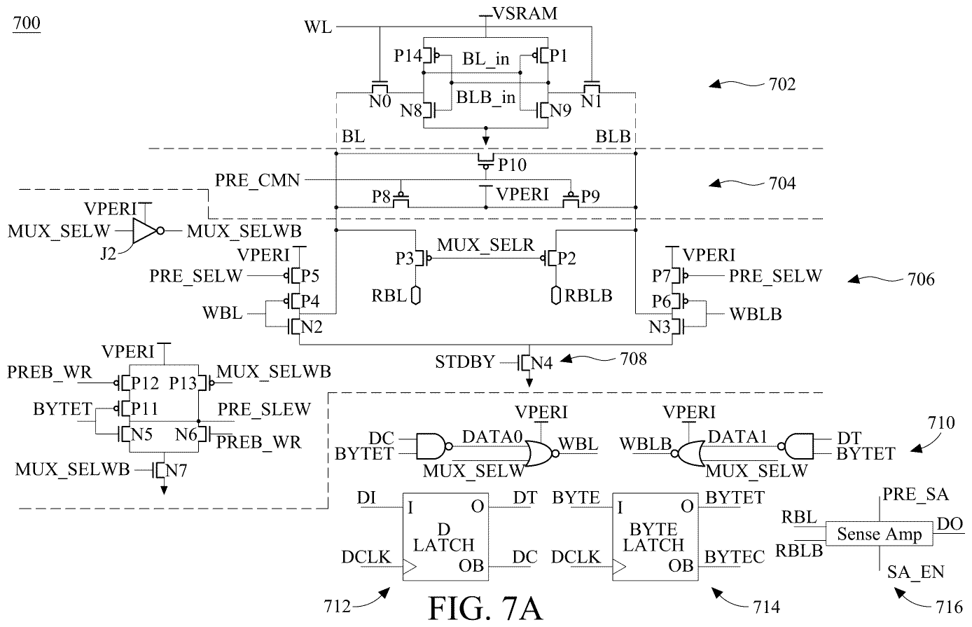

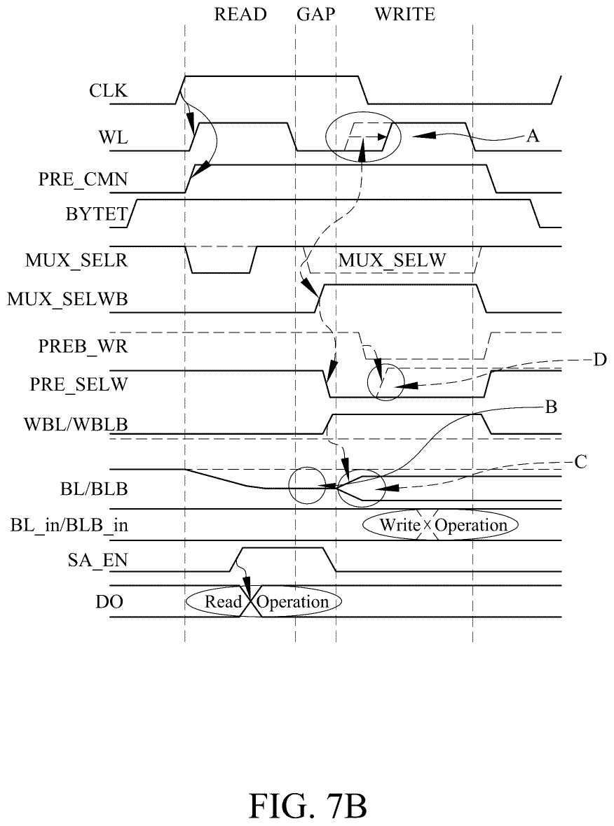

FIG. 7A is a schematic diagram of an electronic device 700 in accordance with some embodiments of the present invention. As shown in FIG. 7A, the electronic device 700 includes a bitcell 702, a precharge circuit 704, a read-write multiplexer 706, a footer device 708, a write driver 710, a first D latch 712, a second D latch 714, and a sense amplifier 716. The main difference between the electronic device 700 and the electronic device 100 is that, the control ends of the p-type transistor P5 and the p-type transistor P7 are electrically connected to a preselection write signal PRE_SELW in the read-write multiplexer 706 of the electronic device 700. The read-write multiplexer 106 of the electronic device 700 further includes an inverter J2, a p-type transistor P12, a p-type transistor P11, a n-type transistor N5, a p-type transistor P13, a n-type transistor N6, and a n-type transistor N7.

The inverter J2 is powered by the operating voltage VPERI. The inverter J2 inverts the mux selection write signal MUX_SELW to generate an inverted mux selection write signal MUX_SELWB. The first end of the p-type transistor P12 is electrically connected to the operating voltage VPERI, and the control end of the p-type transistor P12 is electrically connected to a prewrite signal PREB_WR. The first end of the p-type transistor P11 is electrically connected to the second end of the p-type transistor P12. The second end of the p-type transistor P11 is electrically connected to the preselection write signal PRE_SELW. The control end of the p-type transistor P11 is electrically connected to the latched write-mask IO signal BYTET. The first end of the n-type transistor N5 is electrically connected to the preselection write signal PRE_SELW, and the control end of the n-type transistor N5 is electrically connected to the latched write-mask IO signal BYTET. The first end of the p-type transistor P13 is electrically connected to the operating voltage VPERI, and the control end of the p-type transistor P13 is electrically connected to the inverted mux selection write signal MUX_SELWB. The first end of the n-type transistor N6 is electrically connected to the second end of the p-type transistor P13 which is connected to the preselection write signal PRE_SELW, and the control end of the n-type transistor N6 is electrically connected to the prewrite signal PREB_WR. The first end of the n-type transistor N7 is electrically connected to the second ends of the n-type transistor N5 and the n-type transistor N6. The second end of the n-type transistor N7 is electrically connected to the ground voltage. The control end of the n-type transistor N7 is electrically connected to the inverted mux selection write signal MUX_SELWB.

FIG. 7B is a timing diagram of multiple control signals when the electronic device 700 in FIG. 7 performs the read operation followed by the write operation in accordance with some embodiments of the present invention. As shown in FIG. 7B, the control signals include the clock signal CLK, the waveform on the word line WL, the precharge command signal PRE_CMN, the latched write-mask IO signal BYTET, the mux selection read signal MUX_SELR, the mux selection write signal MUX_SELW, the inverted mux selection write signal MUX_SELWB, the prewrite signal PREB_WR, the preselection write signal PRE_SELW, the write control signals WBL/WBLB, the waveform on the bit lines BL/BLB, the waveform on the bitcell internal lines BL_in/BLB_in, the enable signal SA_EN, and the output signal DO. The read operation starts after the rising edge of the clock signal CLK is triggered. The rising edge of the clock signal CLK then triggers the voltage on the word line WL and the precharge command signal PRE_CMN to be pulled up. The latched write-mask IO signal BYTET is always high during the read operation, the gap period and the write operation. The mux selection read signal MUX_SELR is pulled down to turn on the p-type transistors P2 and P3, so that the sense amplifier 716 is able to sense the bit line voltage on the bit lines BL and BLB during the read operation. At time same time, the bit line voltage on the bit lines BL and BLB is discharged to a predetermined voltage due to the sensing of the bit line voltage by the sense amplifier 716. The voltage on the bitcell internal lines BL_in/BLB_in is unchanged during the read operation. The enable signal SA_EN is pulled high during the read operation, so that the read operation is performed by the sense amplifier 716 and output signal DO is generated. The pulled high mux selection write signal MUX_SELW and the pulled low write control signals WBL/WBLB enable the read-write multiplexer 706 to float the predetermined voltage during the read operation and the gap period, for example, action B in FIG. 7B.

After the voltage on the word line WL is pulled low, the gap period between the read operation and the write operation starts. The mux selection write signal MUX_SELW is pulled low during the gap period, the word line generation block 300 generates a delay period between the mux selection write signal MUX_SELW and the voltage on the word line WL after the gap period and before the write operation is performed, for example, action A in FIG. 7B. The write control signals WBL/WBLB are pulled up during the gap period, so that the read-write multiplexer 706 is triggered to charge the predetermined voltage to a required high voltage for the write operation, such as the operating voltage VPERI, or discharge the predetermined voltage to a required low voltage, such as a ground voltage, based on data being written into the bitcell (DI) after the gap period, for example, action C in FIG. 7B. The falling down of the mux selection write signal MUX_SELW triggers the inverted mux selection write signal MUX_SELWB to pull up during the gap period. The inverted mux selection write signal MUX_SELWB triggers the preselection write signal PRE_SELW to pull down during the gap period. The falling down of the prewrite signal PREB_WR triggers the preselection write signal PRE_SELW to pull up early when the IO signal BYTE is at the logic low level. That is, when the IO signal BYTE is at the logic low level, the preselection write signal PRE_SELW rises up early based on the prewrite signal PREB_WR falling down during the write operation to avoid a static noise margin (SNM) issue, for example, action D in FIG. 7B. In some embodiments of FIG. 7B, the prewrite signal PREB_WR, the IO signal BYTE and the inverted mux selection write signal MUX_SELWB are mixed to generate the preselection write signal PRE_SELW, which can be precharged to the logic high level, for example, “1” before the voltage on the word line is on for BYTE=1 case, which turns off the p-type transistors P5 and P7, thus eliminating the SNM issue of the bitcell 702.

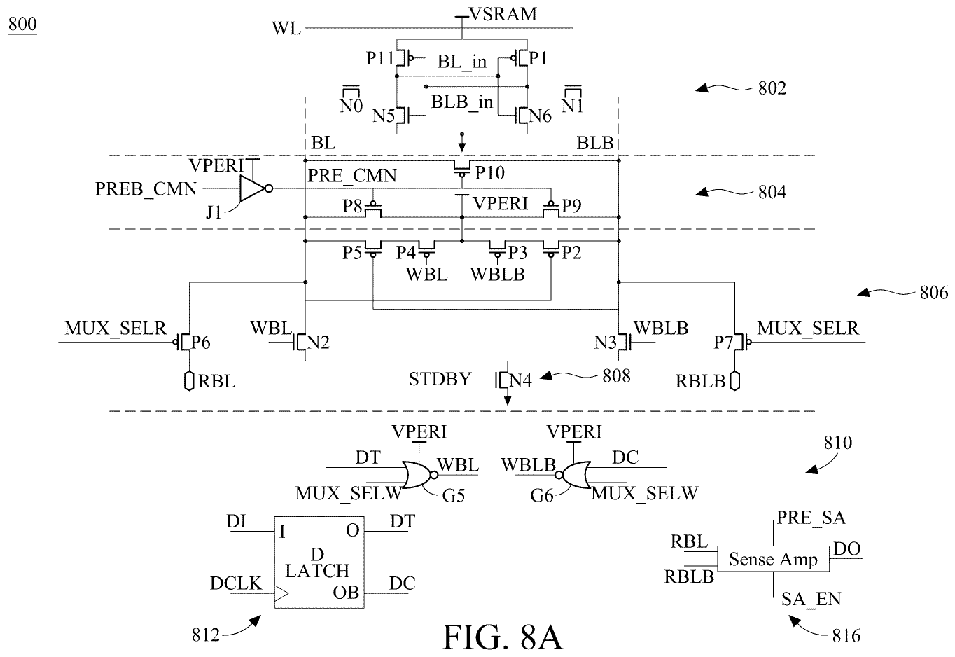

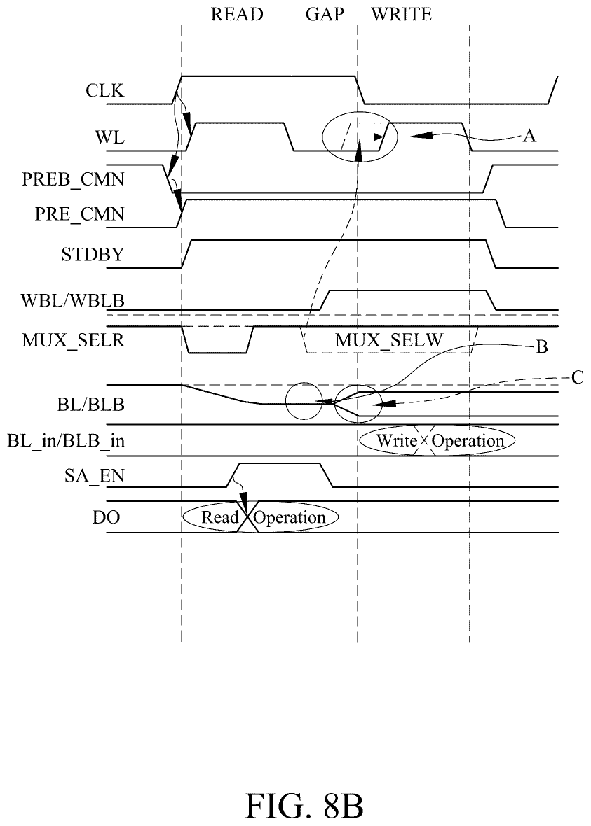

FIG. 8A is a schematic diagram of an electronic device 800 in accordance with some embodiments of the present invention. As shown in FIG. 8A, the electronic device 800 includes a bitcell 802, a precharge circuit 804, a read-write multiplexer 806, a footer device 808, a write driver 810, a D latch 812, and a sense amplifier 816. The main difference between the electronic device 800 and the electronic device 700 is that, the precharge circuit 804 is different from the precharge circuit 704, the read-write multiplexer 806 is different from the read-write multiplexer 706, and the write driver 810 is different from the write driver 710. The precharge circuit 804 includes a p-type transistor P8, a p-type transistor P9, a p-type transistor P10, and an inverter J1. The first end of the p-type transistor P8 is electrically connected to the bit line BL. The second end of the p-type transistor P8 is electrically connected to the operating voltage VPERI. The control end of the p-type transistor P8 is electrically connected to the precharge command signal PRE_CMN. The first end of the p-type transistor P9 is electrically connected to the operating voltage VPERI. The second end of the p-type transistor P9 is electrically connected to the bit line BLB. The control end of the p-type transistor P9 is electrically connected to the precharge command signal PRE_CMN. The inverter J1 is powered by the operating voltage VPERI. The inverter J1 is electrically connected to the control ends of the p-type transistor P8, the second p-type transistor P9, and the p-type transistor P10. The inverter J1 inverses an inversed precharge command signal PREB_CMN to generate the precharge command signal PRE_CMN, and sends the precharge command signal PRE_CMN to the p-type transistor P8, the p-type transistor P9, and the p-type transistor P10.

The read-write multiplexer 806 includes a p-type transistor P2, a p-type transistor P3, a p-type transistor P4, a p-type transistor P5, a p-type transistor P6, a p-type transistor P7, a n-type transistor N2, and a n-type transistor N3. The first end of the p-type transistor P6 is electrically connected to the bit line BL, the second end of the p-type transistor P6 is electrically connected to the read sensing signal RBL, and the control end of the p-type transistor P6 is electrically connected to the mux selection read signal MUX_SELR. The first end of the n-type transistor N2 is electrically connected to the first end of the p-type transistor P6, the second end of the n-type transistor N2 is electrically connected to the footer device 808, and the control end of the n-type transistor N2 is electrically connected to the write control signals WBL. The first end of the p-type transistor P7 is electrically connected to the bit line BLB, the second end of the p-type transistor P7 is electrically connected to the read sensing signal RBLB, and the control end of the p-type transistor P7 is electrically connected to the mux selection read signal MUX_SELR.

The first end of the n-type transistor N3 is electrically connected to the first end of the p-type transistorP7, the second end of the n-type transistor N3 is electrically connected to the second end of the n-type transistor N2, and the control end of the n-type transistor N3 is electrically connected to the write control signal WBLB. The first end of the p-type transistor P5 is electrically connected to the bit line BL, and the control end of the p-type transistor P5 is electrically connected to the bit line BLB. The first end of the p-type transistor P4 is electrically connected to the second end of the p-type transistor P5, the second end of the p-type transistor P4 is electrically connected to the operating voltage VPERI, and the control end of the p-type transistor P4 is electrically connected to the write control signal WBL. The first end of the p-type transistor P3 is electrically connected to the operating voltage VPERI, and the control end of the p-type transistor P3 is electrically connected to the write control signal WBLB. The first end of the p-type transistor P2 is electrically connected to the second end of the p-type transistor P3, the second end of the p-type transistor P2 is electrically connected to the bit line BLB, and the control end of the p-type transistor P2 is electrically connected to the bit line BL.

The write driver 810 includes a NOR gate G5 and a NOR gate G6. Both the NOR gate G5 and NOR gate G6 are powered by the operating voltage VPERI. The NOR gate G5 performs the NOR operation on the latch result DT and the mux selection write signal MUX_SELW to obtain the write control signal WBL. The NOR gate G6 performs the NOR operation on the inversed latch result DC and the mux selection write signal MUX_SELW to obtain the write control signal WBLB.

FIG. 8B is a timing diagram of multiple control signals when the electronic device 800 in FIG. 8 performs the read operation followed by the write operation in accordance with some embodiments of the present invention. As shown in FIG. 8B, the control signals include the clock signal CLK, the waveform on the word line WL, the inversed precharge command signal PREB_CMN, the precharge command signal PRE_CMN, the standby signal STDBY, a mux selection read signal MUX_SELR, the mux selection write signal MUX_SELW, the write control signals WBL/WBLB, the waveform on the bit lines BL/BLB, the waveform on the bitcell internal lines BL_in/BLB_in, the enable signal SA_EN, and the output signal DO. The read operation starts after the rising edge of the clock signal CLK is triggered. The rising edge of the clock signal CLK then triggers the voltage on the word line WL and the precharge command signal PRE_CMN to be pulled up. The standby signal STDBY is pulled up after the read operation starts. The mux selection read signal MUX_SELR is pulled down to turn on the p-type transistors P6 and P7, so that the sense amplifier 816 is able to sense the bit line voltage on the bit lines BL and BLB during the read operation. At time same time, the bit line voltage on the bit lines BL and BLB is discharged to a predetermined voltage due to the sensing of the bit line voltage by the sense amplifier 816. The waveform on the bitcell internal lines BL_in/BLB_in is unchanged during the read operation. The enable signal SA_EN is pulled high during the read operation, so that the read operation is performed by the sense amplifier 816 and output signal DO is generated. The pulled high mux selection write signal MUX_SELW and the pulled low write control signals WBL/WBLB enable the read-write multiplexer 806 to float the predetermined voltage during the read operation and the gap period, for example, action B in FIG. 8B.

After the voltage on the word line WL is pulled low, the gap period between the read operation and the write operation starts. The mux selection write signal MUX_SELW is pulled low during the gap period, the word line generation block 300 generates a delay period between the mux selection write signal MUX_SELW and the voltage on the word line WL after the gap period and before the write operation is performed, for example, action A in FIG. 8B. The write control signals WBL/WBLB are pulled up during the gap period, so that the read-write multiplexer 806 is triggered to charge the predetermined voltage to a required high voltage for the write operation, such as the operating voltage VPERI, or discharge the predetermined voltage to a required low voltage, such as a ground voltage, based on data being written into the bitcell (DI) after the gap period, for example, action C in FIG. 8B. Since the IO signal BYTE is not present, the electronic device 800 uses the precharge command signal PRE_CMN which is at the logic high level throughout the read-write cycle, hence no intermediate bit line precharge occurs. Therefore, the dynamic power is saved.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An electronic device, comprising:
a bitcell, electrically connected between a word line and a pair of bit lines, configured to perform a read operation followed by a write operation; wherein there is a gap period between the read operation and the write operation;
a read-write multiplexer, electrically connected to the pair of bit lines, configured to discharge a bit line voltage on the pair of bit lines from an operating voltage to a predetermined voltage during the read operation, float the predetermined voltage during the gap period, and charge the predetermined voltage to the operating voltage or discharge the predetermined voltage to a ground voltage based on data being written into the bitcell after the gap period, and
a word line generation block, configured to generate a delay period between a mux selection write signal and a voltage on the word line after the gap period and before the write operation is performed.

2. The electronic device as claimed in claim 1, further comprising:
a precharge circuit, electrically connected between the bitcell and the read-write multiplexer through the pair of bit lines, configured to precharge the bit line voltage on the pair of bit lines to the operating voltage based on a precharge command signal.

3. The electronic device as claimed in claim 2, further comprising:
a read clock generation circuit, configured to trigger a rising edge of a word line voltage on the word line during the read operation based on an internal-clock read signal;
a common clock generation circuit, configured to generate a precharge command signal to control the precharge circuit for precharging; and
a write clock generation circuit, electrically connected to the read clock generation circuit and the common clock generation circuit, configured to trigger the rising edge of the word line voltage on the word line during the write operation based on an internal-clock gap signal.

4. The electronic device as claimed in claim 3, wherein the read clock generation circuit receives a read command signal and a clock signal to generate the internal-clock read signal, and generates the internal-clock gap signal based on the internal-clock read signal.

5. The electronic device as claimed in claim 3,
wherein the common clock generation circuit receives a read command signal, a write command signal, and a clock signal to generate an internal-clock common signal;
wherein the common clock generation circuit generates the precharge command signal based on the internal-clock common signal.

6. The electronic device as claimed in claim 4,
wherein the write clock generation circuit is electrically connected to the read clock generation circuit and the common clock generation circuit, and the write clock generation circuit receives a write command signal and generates an internal-clock write signal based on write command signal.

7. The electronic device as claimed in claim 5,
wherein the common clock generation circuit generates a mux selection read signal and the mux selection write signal based on the internal-clock read signal and an internal-clock selection write signal;
wherein the internal-clock selection write signal is generated by the write clock generation circuit based on the write command signal.

8. The electronic device as claimed in claim 7, wherein the common clock generation circuit controls the read-write multiplexer based on the mux selection read signal and the mux selection write signal.

9. The electronic device as claimed in claim 5, wherein the common clock generation circuit includes a reset multiplexer; and the reset multiplexer resets the internal-clock common signal based on the read operation or the write operation.

10. The electronic device as claimed in claim 5,
wherein when the read command signa is at a logic high level and the write command signal is at a logic low level, the bitcell performs the read operation;
wherein when the read command signal is at the logic low level and the write command signal is at the logic high level, the bitcell performs the write operation;
wherein when the read command signal and the write command signal are both at the logic high level, the bitcell performs the read operation followed by the write operation; and
wherein when the read command signal and the write command signal are both at the logic low level, the bitcell performs no operation.

11. The electronic device as claimed in claim 1, further comprising:
a footer device, electrically connected to the read-write multiplexer, configured to reduce current leakage based a standby signal;
wherein the standby signal is asserted early before the gap period.

12. The electronic device as claimed in claim 2, further comprising:
a sense amplifier, electrically connected to the read-write multiplexer, configured to sense the bit line voltage on the pair of bit lines through a pair of read sensing signals; and
a write driver, electrically connected to the read-write multiplexer, configured to write the data into the bitcell through a pair of write control signals.

13. The electronic device as claimed in claim 12, wherein the read-write multiplexer comprises:
a first p-type transistor, comprising a first end, a second end, and a control end, wherein the first end is electrically connected to one of the pair of bit lines, the second end is electrically connected to one of the pair of read sensing signals, and the control end is electrically connected to a mux selection read signal;
a second p-type transistor, comprising a first end, a second end, and a control end, wherein the first end is electrically connected to the other one of the pair of bit lines, the second end is electrically connected to the other one of the pair of read sensing signals, and the control end is electrically connected to the control end of the first p-type transistor;
a third p-type transistor, comprising a first end, a second end, and a control end, wherein the first end is electrically connected to the operating voltage, and the control end is electrically connected to the mux selection write signal;
a fourth p-type transistor, comprising a first end, a second end, and a control end, wherein the first end is electrically connected to the second end of the third p-type transistor, the second end is electrically connected to one of the pair of bit lines, and the control end is electrically connected to one of the pair of write control signals;
a first n-type transistor, comprising a first end, a second end, and a control end, wherein the first end is electrically connected to the second end of the fourth p-type transistor, the second end is electrically connected to the footer device, and the control end is electrically connected to the control end of the fourth p-type transistor;
a fifth p-type transistor, comprising a first end, a second end, and a control end, wherein the first end is electrically connected to the operating voltage, and the control end is electrically connected to the mux selection write signal;
a sixth p-type transistor, comprising a first end, a second end, and a control end, wherein the first end is electrically connected to the second end of the fifth p-type transistor, the second end is electrically connected to the other one of the pair of bit lines, and the control end is electrically connected to the other one of the pair of write control signals; and
a second n-type transistor, comprising a first end, a second end, and a control end, wherein the first end is electrically connected to the second end of the sixth p-type transistor, the second end is electrically connected to the footer device, and the control end is electrically connected to the control end of the sixth p-type transistor.

14. The electronic device as claimed in claim 13, wherein the control ends of the third p-type transistor and the fifth p-type transistor are electrically connected to a preselection write signal; wherein the read-write multiplexer further comprises:
an inverter, powered by the operating voltage, configured to invert the mux selection write signal to generate an inverted mux selection write signal;
a seventh p-type transistor, comprising a first end, a second end, and a control end, wherein the first end is electrically connected to the operating voltage, and the control end is electrically connected to a prewrite signal;
an eighth p-type transistor, comprising a first end, a second end, and a control end, wherein the first end is electrically connected to the second end of the seventh p-type transistor, the second end is electrically connected to the preselection write signal, and the control end is electrically connected to a latched write-mask IO signal;
a third n-type transistor, comprising a first end, a second end, and a control end, wherein the first end is electrically connected to the preselection write signal, and the control end is electrically connected to the latched write-mask IO signal;
a ninth p-type transistor, comprising a first end, a second end, and a control end, wherein the first end is electrically connected to the operating voltage, and the control end is electrically connected to the inverted mux selection write signal;
a fourth n-type transistor, comprising a first end, a second end, and a control end, wherein the first end is electrically connected to the second end of the ninth p-type transistor which is connected to the preselection write signal, and the control end is electrically connected to the prewrite signal; and
a fifth n-type transistor, comprising a first end, a second end, and a control end, wherein the first end is electrically connected to the second ends of the third n-type transistor and fourth n-type transistor, the second end is electrically connected to the ground voltage, and the control end is electrically connected to the inverted mux selection write signal.

15. The electronic device as claimed in claim 14, wherein an IO signal and latched write-mask IO signal is present; when the IO signal is at a logic low level, the preselection write signal rises up early based on the prewrite signal falling down during the write operation to avoid a static noise margin (SNM) issue.

16. The electronic device as claimed in claim 12, wherein the precharge circuit comprises:
a first p-type transistor, comprising a first end, a second end, and a control end, wherein the first end is electrically connected to one of the pair of bit lines, the second end is electrically connected to the operating voltage, and the control end is electrically connected to the precharge command signal;
a second p-type transistor, comprising a first end, a second end, and a control end, wherein the first end is electrically connected to the operating voltage, the second end is electrically connected to the other one of the pair of bit lines, and the control end is electrically connected to the precharge command signal; and
a third p-type transistor, comprising a first end, a second end, and a control end, wherein the first end is electrically connected to one of the pair of bit lines, the second end is electrically connected to the other one of the pair of bit lines, and the control end is electrically connected to the precharge command signal.

17. The electronic device as claimed in claim 16, wherein the precharge circuit further comprises:
an inverter, powered by the operating voltage, electrically connected to the control ends of the first p-type transistor, the second p-type transistor, and the third p-type transistor, configured to inverse an inversed precharge command signal to generate the precharge command signal, and send the precharge command signal to the first p-type transistor, the second p-type transistor, and the third p-type transistor.

18. The electronic device as claimed in claim 17, wherein the read-write multiplexer comprises:
a fourth p-type transistor, comprising a first end, a second end, and a control end, wherein the first end is electrically connected to one of the pair of bit lines, the second end is electrically connected to one of the pair of read sensing signals and the control end is electrically connected to a mux selection read signal;
a first n-type transistor, comprising a first end, a second end, and a control end, wherein the first end is electrically connected to the first end of the fourth p-type transistor, the second end is electrically connected to a footer device, and the control end s electrically connected to one of the pair of write control signals;
a fifth p-type transistor, comprising a first end, a second end, and a control end, wherein the first end is electrically connected to the other one of the pair of bit lines, the second end is electrically connected to the other one of the pair of read sensing signals, and the control end is electrically connected to the mux selection read signal;
a second n-type transistor, comprising a first end, a second end, and a control end, wherein the first end is electrically connected to the first end of the fifth p-type transistor, the second end is electrically connected to the second end of the first n-type transistor, and the control end is electrically connected to the other one of the pair of write control signals;
a sixth p-type transistor, comprising a first end, a second end, and a control end, wherein the first end is electrically connected to one of the pair of bit lines, and the control end is electrically connected to the other one of the pair of bit lines;
a seventh p-type transistor, comprising a first end, a second end, and a control end, wherein the first end is electrically connected to the second end of the sixth p-type transistor, the second end is electrically connected to the operating voltage, and the control end is electrically connected to one of the pair of write control signals;
an eighth p-type transistor, comprising a first end, a second end, and a control end, wherein the first end is electrically connected to the operating voltage, and the control end is electrically connected to the other one of the pair of write control signals; and
a ninth p-type transistor, comprising a first end, a second end, and a control end, wherein the first end is electrically connected to the second end of the eighth p-type transistor, the second end is electrically connected to the other one of the pair of bit lines, and the control end is electrically connected to one of the pair of bit lines.

19. The electronic device as claimed in claim 12, further comprising:
a first D latch, comprising a data input end, a clock input end, a data output end, and an inversed data output end, configured to receive the data being written into the bitcell through the data input end, receive a D-latch clock signal through the clock input end, and output a latch result through the data output end and an inversed latch result through the inversed data output end based on the data being written into the bitcell and the D-latch clock signal; and
a second D latch, comprising a data input end, a clock input end, a data output end, and an inversed data output end, configured to receive an IO signal through the data input end, receive the D-latch clock signal through the clock input end, and output a latched write-mask IO signal through the data output end based on the IO signal and the D-latch clock signal.

20. The electronic device as claimed in claim 19, wherein the write driver comprises:
a first NAND gate, configured to perform a NAND operation on the inversed latch result and the latched write-mask IO signal to obtain a first intermediate result;
a first NOR gate, powered by the operating voltage, configured to perform a NOR operation on the first intermediate result and the mux selection write signal to obtain one of the pair of write control signals;
a second NAND gate, configured to perform the NAND operation on the latch result and the latched write-mask IO signal to obtain a second intermediate result; and
a second NOR gate, powered by the operating voltage, configured to perform the NOR operation on the second intermediate result and the mux selection write signal to obtain the other one of the pair of write control signals.
